(19) United States
(12) Patent Application Publication
(10) Pub. No.: US 2022/0181601 A1
(43) Pub. Date: Jun. 9, 2022

(54) PRE-LITHIATION AND LITHIUM METAL-FREE ANODE COATINGS

(71) Applicant: Applied Materials, Inc., Santa Clara, CA (US)

(72) Inventors: Alejandro SEVILLA, Miami, FL (US); Ezhiylmurugan RANGASAMY, San Jose, CA (US); Subramanya P. HERLE, Mountain View, CA (US); David Masayuki ISHIKAWA, Mountain View, CA (US)

(21) Appl. No.: 17/543,322

(22) Filed: Dec. 6, 2021

Related U.S. Application Data
(60) Provisional application No. 63/122,856, filed on Dec. 8, 2020.

(51) Int. Cl. H01M 4/04

(52) U.S. Cl. CPC H01M 4/0488; H01M 4/0471; H01M 4/0419; H01M 4/0404; H01M 4/0485

(57) ABSTRACT

A method and system for forming lithium anode devices are provided. In one embodiment, the methods and systems form pre-lithiated Group-IV alloy-type nanoparticles (NP's), for example, Li—Z where Z is Ge, Si, or Sn. In another embodiment, the methods and systems synthesize Group-IV nanoparticles and alloy the Group-IV nanoparticles with lithium. The Group-IV nanoparticles can be made on demand and premixed with anode materials or coated on anode materials. In yet another embodiment, the methods and systems form lithium metal-free silver carbon (“Ag—C”) nanocomposites (NC's). In yet another embodiment, a method utilizing silver (PVD) and carbon (PECVD) co-deposition to make anode coatings that can regulate lithium nucleation energy to minimize dendrite formation is provided.

### CROSS-REFERENCE TO RELATED APPLICATIONS

This application claims benefit to U.S. Prov. Appl. No. 63/122,856, filed on Dec. 8, 2020, which is herein incorporated by reference.

### BACKGROUND

### Field

Embodiments described herein generally relate to deposition systems and methods for processing a flexible substrate. More specifically, embodiments relate to systems and methods of forming anode structures on a flexible substrate.

### Description of the Related Art

Rechargeable electrochemical storage systems are increasing in importance for many fields of everyday life. High-capacity energy storage devices, such as lithium-ion (Li-ion) batteries and capacitors, are used in a growing number of applications, including portable electronics, medical, transportation, grid-connected large energy storage, renewable energy storage, and uninterruptible power supply (UPS). In each of these applications, the charge/discharge time and capacity of energy storage devices are key parameters. In addition, the size, weight, and/or cost of such energy storage devices are also key parameters. Further, low internal resistance is integral for high performance. The lower the resistance, the less restriction the energy storage device encounters in delivering electrical energy. For example, in the case of a battery, internal resistance affects performance by reducing the total amount of useful energy stored by the battery as well as the ability of the battery to deliver high current.

Li-ion batteries are thought to have the best chance at achieving the sought after capacity and cycling. However, Li-ion batteries as currently constituted often lack the energy capacity and number of charge/discharge cycles for these growing applications.

Accordingly, there is a need in the art for faster charging, higher capacity energy storage devices that have improved cycling, and can be more cost effectively manufactured. There is also a need for components for an energy storage device that reduce the internal resistance of the storage device.

### SUMMARY

Embodiments described herein generally relate to vacuum deposition systems and methods for processing a flexible substrate. More specifically, embodiments relate to roll-to-roll vacuum deposition systems and methods of forming anode structures on a flexible substrate.

In one or more embodiments, a method of making a lithiated Group-IV nanoparticle is provided. The method includes introducing a layer of Group-IV nanoparticles into a heated mixing vessel. The method further includes introducing a layer comprising lithium into the heated mixing vessel. The method further includes sequentially repeating introducing the layer of Group-IV nanoparticles and the layer comprising lithium into the heated mixing vessel. The method further includes alloying the Group-IV nanoparticles with the lithium to form the lithiated Group-IV nanoparticles.

In other embodiments, the Group-IV nanoparticles are formed from a non-thermal plasma synthesis process. The lithiated Group-IV nanoparticles are an air-stable pre-lithiation reagent. Introducing the layer of Group-IV nanoparticles into the heated mixing vessel comprises supplying molten lithium into the heated mixing vessel. Introducing the layer of Group-IV nanoparticles into the heated mixing vessel comprises supplying lithium powder into the heated mixing vessel. The lithiated Group-IV nanoparticles are applied to a graphite anode to form a pre-lithiated graphite anode. Applying the lithiated Group-IV nanoparticles to a graphite anode to form a pre-lithiated graphite anode comprises an industrial sifter feeder process. Applying the lithiated Group-IV nanoparticles to a graphite anode to form a pre-lithiated graphite anode comprises an electrospray process. The Group-IV nanoparticles are selected from silicon nanoparticles, germanium nanoparticles, tin nanoparticles, carbon nanoparticles, or any combination thereof. The heated mixing vessel is a rotary planetary mixer. The lithiated Group-IV nanoparticles are mixed to form a slurry. Mixing the lithiated Group-IV nanoparticles to form the slurry comprises mixing the lithiated Group-IV nanoparticles with a conductive additive, a binding agent, a solvent, or any combination thereof. The slurry is cast over an anode structure to form a pre-lithiated alloy-type anode.

In some embodiments, a system for forming an anode structure is provided. The system includes a lithium source module operable to supply lithium. The system further includes a Group-IV nanoparticle source module operable to supply Group-IV nanoparticles. The system further includes a mixing vessel assembly, wherein the mixing vessel assembly is capable of heating the lithium and the Group-IV nanoparticles to produce pre-lithiated Group-IV alloy-type nanoparticles.

In one or more embodiments, the system further includes a deposition source module operable to deposit the pre-lithiated Group-IV alloy-type nanoparticles over a substrate. The deposition source module includes a sifter body; a hopper assembly; and a delivery conduit fluidly coupling the hopper assembly with the sifter body. The deposition source module includes a deposition module that defines a processing environment; a coating drum positioned in the processing environment and operable to transfer a flexible substrate; and an electrospray gun positioned in the processing environment and operable to deposit the pre-lithiated Group-IV alloy-type nanoparticles on the flexible substrate. The electrospray gun is a triboelectric powder spray gun or a corona spray gun. The system further includes a hopper assembly operable for storing and supplying the lithiated Group-IV alloyed nanoparticles to the electrospray gun.

In other embodiments, a method of forming an anode structure is provided. The method includes forming a silver-carbon (Ag—C) nanocomposite over a current collector web. Forming the silver-carbon (Ag—C) nanocomposite includes sputtering silver over the current collector web concurrently with plasma-enhanced chemical vapor deposition of amorphous carbon to form the silver-carbon nanocomposite over the current collector.

In one or more embodiments, a layer of lithium is deposited on or over the silver-carbon nanocomposite. The layer of lithium can be deposited over the silver-carbon nanocomposite by thermally evaporating lithium. Sputtering silver over the current collector is performed using a DC sputtering gun.

In other embodiments, a flexible substrate coating system is provided. The system includes an unwinding module housing a feed reel capable of providing a continuous sheet of flexible material. The method further includes a winding module housing a take-up reel capable of storing the continuous sheet of flexible material. The method further includes a processing module arranged downstream from the unwinding module. The processing module includes a plurality of sub-chambers arranged in sequence, each configured to perform one or more processing operations to the continuous sheet of flexible material. The system further includes a coating drum capable of guiding the continuous sheet of flexible material past the plurality of sub-chambers along a travel direction, wherein the sub-chambers are radially disposed about the coating drum. A first sub-chamber of the plurality of sub-chambers includes a first deposition source operable to deposit silver and a second deposition source operable to deposit carbon.

In one or more embodiments, the first deposition source is a physical vapor deposition (PVD) source and the second deposition source is a plasma-enhanced chemical vapor deposition (PECVD) source. The physical vapor deposition source includes a DC sputtering gun and the PECVD source comprises an electrode showerhead. The first sub-chamber is defined by a sub-chamber body with an edge shield positioned over the sub-chamber body. The edge shield has one or more apertures defining a pattern of evaporated material that is deposited on the continuous sheet of flexible material. The coating system further includes a second sub-chamber including a thermal evaporation source. The thermal evaporation source is configured to deposit lithium metal.

In other embodiments, a method of forming a lithium-free silver-carbon (Ag—C) based slurry is provided. The method includes forming silver nanoparticles via a spray pyrolysis process. The method further includes combining the silver nanoparticles with a conductive additive, a binding agent, and a solvent in a heated mixing vessel to form the lithium-free silver-carbon (Ag—C) based slurry.

Embodiments can include one or more of the following. The conductive additive is selected from the group of graphite, graphene hard carbon, carbon black, carbon coated silicon, or any combination thereof. The binding agent is selected from styrene-butadiene rubber, acrylated styrene-butadiene rubber, acrylonitrile copolymer, acrylonitrile-butadiene rubber, nitrile butadiene rubber, acrylonitrile-styrene-butadiene copolymer, acryl rubber, butyl rubber, fluorine rubber, polytetrafluoroethylene, polyethylene, polypropylene, ethylene/propylene copolymers, polybutadiene, polyethylene oxide, chlorosulfonated polyethylene, polyvinylpyrrolidone, polyvinylpyridine, polyvinyl alcohol, polyvinyl acetate, polyepichlorohydrin, polyphosphazene, polyacrylonitrile, polystyrene, latex, acrylic resins, phenolic resins, epoxy resins, carboxymethyl cellulose, hydroxypropyl cellulose, cellulose acetate, cellulose acetate butyrate, cellulose acetate propionate, cyanoethylcellulose, cyanoethylsucrose, polyester, polyimide, polyether, polyimide, polycarboxylate, polycarboxylic acid, polyacrylic acid, polyacrylate, polymethacrylic acid, polymethacrylate, polyacrylamide, polyurethane, fluorinated polymer, chlorinated polymer, a salt of alginic acid, polyvinylidene fluoride, poly(vinylidene fluoride)-hexafluoropropene, or any combination thereof. The solvent is selected from N-methyl-2-pyrrolidone, dimethylformamide, dimethyl sulfoxide, acetonitrile, butylene carbonate, propylene carbonate, ethyl bromide, tetrahydrofuran, dimethyl carbonate, diethyl carbonate, ethyl methyl, carbonate methyl propyl carbonate, ethylene carbonate, water, pure water, de-ionized water, distilled water, ethanol, isopropanol, methanol, acetone, n-propanol, t-butanol, or any combination thereof.

In some embodiments, a non-transitory computer readable medium has stored thereon instructions, which, when executed by a processor, causes the processor to perform operations of the above apparatus and/or method.

### BRIEF DESCRIPTION OF THE DRAWINGS

So that the manner in which the above-recited features of the present disclosure can be understood in detail, a more particular description of the embodiments, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a schematic cross-sectional view of one example of a flexible layer stack formed according to one or more embodiments described herein.

FIG. 2 illustrates a process flow chart summarizing one embodiment of a method of forming an anode structure according to one or more embodiments.

FIG. 3 illustrates a schematic view of a system for forming an anode structure according to one or more embodiments.

FIG. 4 illustrates a schematic view of one example of a lithium source system according to one or more embodiments.

FIG. 5 illustrates a schematic view of another example of a lithium source system according to one or more embodiments.

FIG. 6 illustrates a schematic view of one example of a Group-IV nanoparticle source system according to one or more embodiments.

FIG. 7 illustrates a schematic view of another example of a Group-IV nanoparticle source system according to one or more embodiments.

FIG. 8 illustrates a schematic view of a mixing vessel assembly according to one or more embodiments.

FIG. 9 illustrates a schematic view of a deposition system according to one or more embodiments.

FIG. 10 illustrates a schematic view of another deposition system according to one or more embodiments.

FIG. 11 illustrates a process flow chart summarizing a method of forming a silver-carbon (Ag—C) nanocomposite according to one or more embodiments.

FIG. 12 illustrates a schematic view of a system for forming a silver-carbon (Ag—C) nanocomposite according to one or more embodiments.

FIG. 13 illustrates a schematic view of another system for forming a silver-carbon (Ag—C) nanocomposite according to one or more embodiments.

FIG. 14 illustrates a schematic view of a system for forming a silver-carbon (Ag—C) slurry according to one or more embodiments.

FIG. 15 illustrates a schematic view of a spray pyrolysis system according to one or more embodiments.

To facilitate understanding, identical reference numerals have been used, where possible, to designate identical elements that are common to the figures. It is contemplated that elements and features of one embodiment may be beneficially incorporated In other embodiments without further recitation.

### DETAILED DESCRIPTION

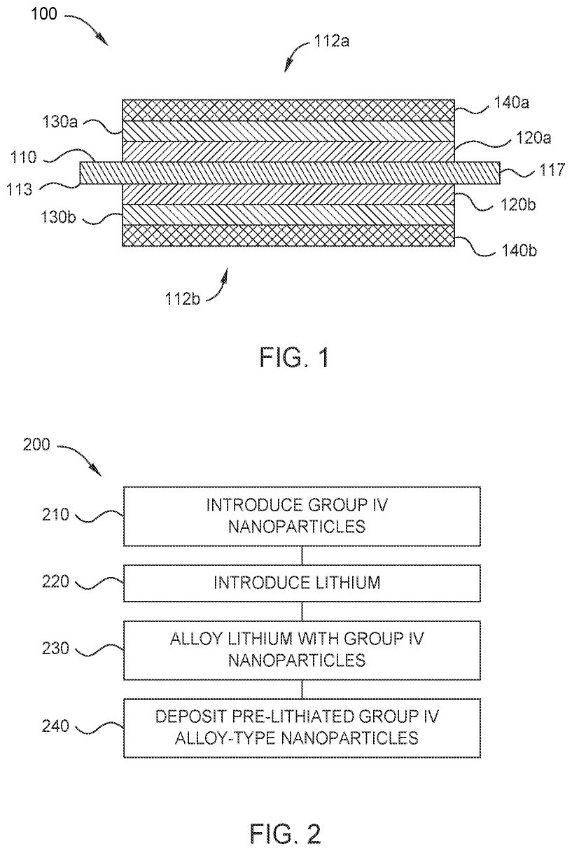

The following disclosure describes systems and methods of forming anode structures on a flexible substrate. Certain details are set forth in the following description and in FIGS. 1-15 to provide a thorough understanding of various embodiments of the disclosure. Other details describing well-known structures and systems often associated with energy storage devices and anode structures are not set forth in the following disclosure to avoid unnecessarily obscuring the description of the various embodiments.

Many of the details, dimensions, angles and other features shown in the Figures are merely illustrative of particular embodiments. Accordingly, other embodiments can have other details, components, dimensions, angles and features without departing from the spirit or scope of the present disclosure. In addition, further embodiments of the disclosure can be practiced without several of the details described below.

Some embodiments described herein will be described below in reference to a roll-to-roll coating system, such as a TopMet® roll-to-roll web coating system, a SMARTWEB® roll-to-roll web coating system, a TOPBEAM® roll-to-roll web coating system, all of which are available from Applied Materials, Inc. of Santa Clara, Calif. Other tools capable of performing high rate deposition processes may also be adapted to benefit from the embodiments described herein. In addition, any system enabling the deposition processes described herein can be used to advantage. The apparatus description described herein is illustrative and should not be construed or interpreted as limiting the scope of the embodiments described herein. It should also be understood that although described as a roll-to-roll process, the embodiments described herein may also be performed on discrete substrates.

Some embodiments described herein will be described below in reference to a roll-to-roll coating system. The apparatus description described herein is illustrative and should not be construed or interpreted as limiting the scope of the embodiments described herein. It should also be understood that although described as a roll-to-roll process, the embodiments described herein can be performed on other types of substrates, for example, discrete substrates.

Some embodiments described herein refer to a coating system adapted for pre-lithiation of a flexible substrate such as a web for lithium-ion battery devices. In particular, the coating system is adapted for continuous processing of a flexible substrate such as a web unwound from an unwinding module. The coating system can be configured in a modular design, for example, an appropriate number of process modules may be arranged adjacent to each other in a processing line, and the flexible substrate is inserted into the first process module and may be ejected from the last process module of the line. Furthermore, the entire coating system may be re-configured if a change of individual processing operations is desired.

It is noted that while the particular substrate on which some embodiments described herein may be practiced is not limited, it is particularly beneficial to practice the embodiments on flexible substrates, including for example, web-based substrates, panels, and discrete sheets. The substrate may also be in the form of a foil, a film, or a thin plate.

It is also noted here that a flexible substrate or web as used within the embodiments described herein can typically be characterized in that the flexible substrate is bendable. The term “web” may be synonymously used with the term “strip” or the term “flexible substrate.” For example, the web as described in embodiments herein may be a foil.

It is further noted that in some embodiments where the substrate is a vertically oriented substrate, the vertically oriented substrate may be angled relative to a vertical plane. For example, In some embodiments, the substrate may be angled from between about 1 degree to about 20 degrees from the vertical plane. In some embodiments where the substrate is a horizontally oriented substrate, the horizontally oriented substrate may be angled relative to a horizontal plane. For example, In some embodiments, the substrate may be angled from between about 1 degree to about 20 degrees from the horizontal plane. As used herein, the term “vertical” is defined as a major surface or deposition surface of the flexible conductive substrate being perpendicular relative to the horizon. As used herein, the term “horizontal” is defined as a major surface or deposition surface of the flexible conductive substrate being parallel relative to the horizon.

Energy storage devices, for example, batteries, typically include a positive electrode, an anode electrode separated by a porous separator, and an electrolyte, which is used as an ion-conductive matrix. Graphite anodes are the current state of the art but the industry is moving from graphite based anodes to silicon blended graphite anodes to increase cell energy density. However, silicon blended graphite anodes often suffer from irreversible capacity loss that occurs during the first cycle. Thus, there is a need for methods for replenishing this first cycle capacity loss. Pre-lithiation of anode materials is one available method for replenishing first cycle capacity loss.

Various anode pre-lithiation methods exist including chemical pre-lithiation, electrochemical pre-lithiation, pre-lithiation by direct contact to lithium metal, and stabilized lithium metal powder (“SLMP™”). These existing pre-lithiation methods share common volume Li-ion battery manufacturing disadvantages, such as, long reaction times and inherent safety risks, which are unsuitable for volume lithium-ion battery manufacture.

For example, for SLMP™, up to 30% of the Li₂CO₃ powder shells remain uncracked. These uncracked shells are then incorporated as inactive material into the cell mass, which reduces energy density of the Li-ion battery. Loose powder particles dislodged within the electrolyte while spreading SLMP™ also present inherent safety and reliability risks. Electrochemical pre-lithiation produces reactive material in ambient air, which can increase cell impedance due to nitrogen and oxygen contamination. Direct contact to lithium metal is a non-uniform and low yield process hindered by thin lithium metal foils sixty centimeters wide and discontinuous at twenty meters long or shorter.

Deposition of lithium metal is another method for replenishing this first cycle capacity loss of silicon blended graphite anode. While there are numerous methods for lithium metal deposition, for example, thermal evaporation, lamination, or printing, handling of lithium metal deposited on a spool before device stacking needs to be addressed, especially in a high-volume manufacturing environment. In order to address these handling issues, anode web coating often involves thin protection layer coatings. In the absence of a protection layer coating, the lithium metal surface is susceptible to adverse corrosion and oxidation. Lithium carbonate (Li₂CO₃) films are currently used as protection layer coating for lithium. However, lithium carbonate protection layers present several challenges. For example, carbonate coatings consume lithium thereby increasing the amount of “dead lithium” and correspondingly decreasing coulombic efficiency. Current deposition processes for lithium carbonate can lead to the formation of lithium oxide, instead of lithium carbonate, which is an undesirable SEI component. In addition, carbonate coatings are difficult to activate given the slow adsorption rate of carbonate, which can cause significant variation in coating uniformity of the carbonate coating in both the machine and transverse directions. Furthermore, CO₂ adsorption lacks line-of-sight scalability and therefore is an unsuitable process for most high volume protection layer coatings including both sacrificial and protective applications.

In one aspect, methods and systems for forming lithium anode devices are provided. In one embodiment, methods and systems for forming pre-lithiated Group-IV alloy-type nanoparticles (NP's), for example, Li—Z where Z is Ge, Si, or Sn, are provided. In another embodiment, methods and systems for synthesizing Group-IV nanoparticles and alloying the Group-IV nanoparticles with lithium are provided. The Group-IV nanoparticles can be made on demand and premixed with anode materials or coated on anode materials. In yet another embodiment, methods and systems for forming lithium metal-free silver carbon (“Ag—C”) nanocomposites (NC's) are provided. In yet another embodiment, a method utilizing silver (PVD) and carbon (PECVD) co-deposition to make anode coatings that can regulate lithium nucleation energy to minimize dendrite formation is provided.

In some embodiments, deposition modules for dispensing lithium and gas synthesized Group-IV nanoparticles in-situ for use as a pre-lithiation reservoir are provided. Providing nanoparticles integrated in slurry reduces the need for hazardous calendaring, which is typically required to break the shells of SLMP™. Further, modules for producing nanocomposite coatings on current collectors provide novel alloying-process control to minimize dendrite formation. Conventional web coaters generally lack the ability for applying air-stable pre-lithiated particles and/or alloying as-deposited metallic lithium films.

In some embodiments, the Li—Z nanoparticles, where Z is Ge, Si, or Sn, or any combination thereof, as described and disclosed herein do not include stabilizing shells, which eliminates the need for hazardous pressure-based cracking activation associated with the cracking of SLMP™ lithium carbonate shells. In one or more embodiments, the Li—Z nanoparticles can contain an atomic ratio of Li:Z of about 1:1, about 1.5:1, about 2:1, about 2.5:1, or about 3:1 to about 3.5:1, about 3.8:1, about 4:1, about 4.2:1, about 4.5:1, about 4.8:1, about 5:1, about 5.5:1, about 6:1, or greater. In some embodiments, the Li—Z nanoparticles described herein are smaller than SLMP™ and therefor can be homogenously or variably dosed on top or through anode materials. In some embodiments, the roll-to-roll web approach of Ag—C nanocomposite layer formation described herein facilitates higher process tunability (carbon matrix porosity, pore anisotropy, and silver immobilization) and higher yield when compared to slurry-based casting methods.

In some embodiments, lithium-germanium alloy nanoparticles, for example, Li₂₂Ge₅ nanoparticles, are obtained from a metallurgical alloying process in which molten lithium and germanium nanoparticles are introduced. Germanium nanoparticles can be obtained from non-thermal plasma synthesis of a germanium-halide source, for example, a GeCl₄ source. Both lithium and germanium nanoparticles can be added in sequencing layers to reduce alloying time. After the process is complete, the particles can be mixed in a slurry form with, for example, carbon additive, a binding agent, and a solvent, to be casted using traditional slurry-based methods, for example, slot-die coating. Alternatively, the Group-IV nanoparticles serve as stable lithium-carrying reagent and are applied onto a graphite-coated current collector using traditional powder coating methods and calendaring followed by heating for adhesion.

In some embodiments, the Ag—C nanocomposite layer is obtained by simultaneously sputtering silver onto a substrate and coating carbon via, for example, plasma-enhanced chemical vapor deposition (PECVD). Optionally, lithium can then be evaporated onto the web to pre-lithiate the Ag—C nanocomposite layer.

FIG. 1 illustrates a schematic cross-sectional view of one example of a flexible layer stack 100 formed according to one or more embodiments described herein. The flexible layer stack 100 can incorporate Group-IV lithium alloy nanoparticles and/or Ag—C nanocomposites as described and disclosed herein. The flexible layer stack 100 can be formed using the methods and systems described herein. The flexible layer stack 100 can be a pre-lithiated anode structure. The flexible layer stack 100 shown in FIG. 1 includes a continuous flexible substrate 110 having a plurality of film stacks 112a, 112b (collectively 112) formed on opposing sides of the continuous flexible substrate 110. Each film stack 112a, 112b includes a first layer 120a, 120b (collectively 120), a second layer 130a, 130b (collectively 130), and optionally a third layer 140a, 140b (collectively 140).

Although the flexible layer stack 100 is shown in FIG. 1 as having three layers on each side of the continuous flexible substrate 110, it will be understood by those of ordinary skill in the art that the flexible layer stack 100 can include a greater or smaller number of layers, which can be provided over, under and/or between the continuous flexible substrate 110, the first layer 120, the second layer 130, and or the third layer 140 as shown in FIG. 1. Although shown as a double-sided structure, it will be understood by those of ordinary skill in the art that the flexible layer stack 100 can also be a single-sided structure with the continuous flexible substrate 110, the first layer 120, the second layer 130, and optionally the third layer 140.

According to some examples described herein, the continuous flexible substrate 110 can include a first material, and/or the first layer 120 can include a second material. Further, the second layer 130 can include a third material. In addition, the third layer 140 can include a fourth material. For instance, the first material can be a conductive material, typically a metal, such as copper (Cu) or nickel (Ni). Furthermore, the continuous flexible substrate 110 can include one or more sub-layers. In one example, the second material can be an anode material constructed from graphite, silicon, silicon-containing graphite, lithium metal, lithium metal foil or a lithium alloy foil (e.g. lithium aluminum alloys), or a mixture of a lithium metal and/or lithium alloy and materials such as carbon (e.g. coke, graphite), nickel, copper, tin, indium, silicon, oxides thereof, or any combination thereof. The second material can further include a binder material. In another example, the second material is a silver-carbon nanocomposite material as described and disclosed herein. The third material can be a pre-lithiation material. In one example, the third material can be a low melting temperature metal, for example, an alkali metal, such as lithium. In another example, the third material includes Group-IV lithium alloy nanoparticles as described and disclosed herein. The fourth material can be a protective film or interleaf film operable to protect the low melting temperature metal of the third layer.

Generally, in prismatic cells, tabs are formed of the same material as the current collector and may be formed during fabrication of the stack, or added later. In some embodiments, as shown in FIG. 1, the continuous flexible substrate 110 extends beyond the film stack 112 and the portions of the continuous flexible substrate 110 extending beyond the film stack 112 can be used as tabs. For example, any of the uncoated portions of the continuous flexible substrate 110 exposed along a near edge 113 of the continuous flexible substrate 110 and/or the uncoated strip along a far edge 117 of the continuous flexible substrate 110 can be used to form tabs.

According to some examples described herein, the continuous flexible substrate 110 can have a thickness equal to or less than about 25 μm, typically equal to or less than 20 μm, specifically equal to or less than 15 μm, and/or typically equal to or greater than 3 μm, specifically equal to or greater than 5 μm. The continuous flexible substrate 110 can be thick enough to provide the intended function and can be thin enough to be flexible. Specifically, the continuous flexible substrate 110 can be as thin as possible so that the continuous flexible substrate 110 can still provide its intended function.

According to some examples described herein, the first layer 120 can have a thickness of equal to or less than 10 μm, typically equal to or less than 8 μm, beneficially equal to or less than 7 μm, specifically equal to or less than 6 μm, in particular equal to or less than 5 μm. According to some examples, the thickness of the first layer 120 can be equal to or less than 4 μm, or equal to or less than 3 μm, or equal to or less than 2 μm.

According to some examples described herein, the second layer 130 can have a thickness of equal to or less than 10 μm, typically equal to or less than 8 μm, beneficially equal to or less than 7 μm, specifically equal to or less than 6 μm, in particular equal to or less than 5 μm. According to some examples, the thickness of the second layer 130 can be equal to or less than 4 μm, or equal to or less than 3 μm, or equal to or less than 2 μm.

The flexible layer stack 100 shown in FIG. 1 can be, for example, a negative electrode of/for a secondary cell, such as a negative electrode or anode of/for a lithium battery. According to some examples described herein, a flexible negative electrode for a lithium battery includes the continuous flexible substrate 110 that can be a current collector including copper and having a thickness of equal to or less than 10 μm, typically equal to or less than 8 μm, beneficially equal to or less than 7 μm, specifically equal to or less than 6 μm, in particular equal to or less than 5 μm. The flexible negative electrode further includes a first layer 120 including graphite and having a thickness of equal to or more than 5 μm and/or equal to or less than 15 μm and a second layer 130 including Group-IV lithium alloy nanoparticles as described and disclosed herein having a thickness of equal to or more than 5 μm and/or equal to or less 15 μm.

According to some examples described herein, a flexible negative electrode for a lithium battery includes the continuous flexible substrate 110 that can be a current collector including copper and having a thickness of equal to or less than 10 μm, typically equal to or less than 8 μm, beneficially equal to or less than 7 μm, specifically equal to or less than 6 μm, in particular equal to or less than 5 μm. The flexible negative electrode further includes a first layer 120 including a silver-carbon (Ag—C) nanocomposite having a thickness of equal to or more than 5 μm and/or equal to or less than 15 μm and a second layer 130 including a lithium metal layer having a thickness of equal to or more than 5 μm and/or equal to or less 15 μm.

According to some examples described herein, a flexible negative electrode for a lithium battery includes the continuous flexible substrate 110 that can be a current collector including copper and having a thickness of equal to or less than 10 μm, typically equal to or less than 8 μm, beneficially equal to or less than 7 μm, specifically equal to or less than 6 μm, in particular equal to or less than 5 μm. The flexible negative electrode further includes a first layer 120 including a silver-carbon (Ag—C) nanocomposite having a thickness of equal to or more than 5 μm and/or equal to or less than 15 μm and a second layer 130 including Group-IV lithium alloy nanoparticles as described and disclosed herein having a thickness of equal to or more than 5 μm and/or equal to or less 15 μm.

FIG. 2 illustrates a process flow chart summarizing one embodiment of a method 200 of forming an anode structure according to one or more embodiments. At operation 210, Group-IV nanoparticles are introduced into a mixing vessel assembly. The mixing vessel assembly can be heated. The Group-IV nanoparticles can include nanoparticles selected from carbon nanoparticles, silicon nanoparticles, germanium nanoparticles, tin nanoparticles, or any combination thereof. In one example, the Group-IV nanoparticles include germanium nanoparticles. At operation 220, lithium is introduced into the heated mixing vessel assembly. Operation 210 and operation 220 can be sequentially repeated to form alternating layers of nanoparticles and lithium within the heated mixing vessel assembly until a desired amount of each component is present in the heated mixing vessel. Not to be bound by theory but it is believed that sequential introduction of the Group-IV nanoparticles and the lithium into the mixing vessel assembly provides for a more homogenous mixture, which reduces alloying time. In some embodiments, operation 220 is performed before operation 210. At operation 230, the Group-IV nanoparticles are alloyed with the lithium to form pre-lithiated Group-IV alloy-type nanoparticles. At operation 240, the pre-lithiated Group-IV alloy-type nanoparticles are deposited over a substrate. Alternatively, the pre-lithiated Group-IV alloy-type nanoparticles can be mixed with other components to form a slurry.

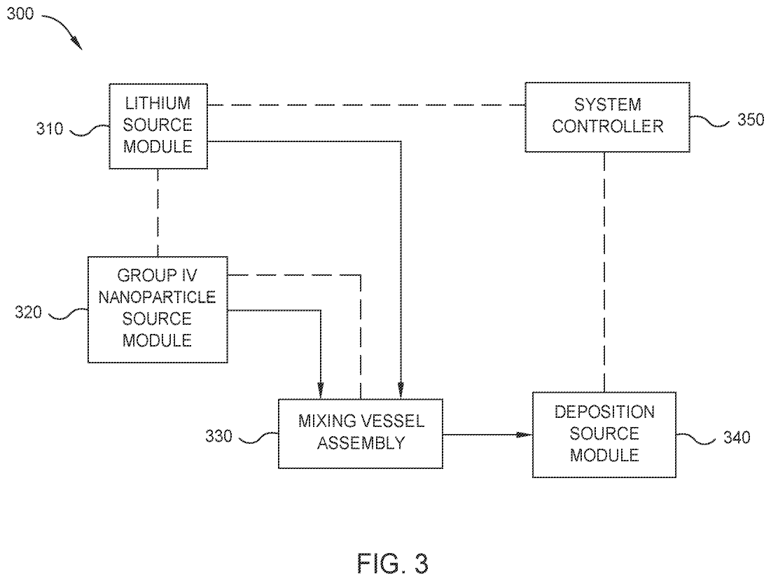

FIG. 3 illustrates a schematic view of a system 300 for forming an anode structure according to one or more embodiments. The system is configured to produce and optionally deposit pre-lithiated Group-IV alloy-type nanoparticles. The system 300 includes a lithium source module 310, a Group-IV nanoparticle source module 320, and a mixing vessel assembly 330. The lithium source module 310 and the Group-IV nanoparticle source module 320 can be fluidly coupled with the mixing vessel assembly 330. The lithium source module 310 supplies lithium to the mixing vessel assembly 330 and the Group-IV nanoparticle source module 320 supplies Group-IV nanoparticles to the mixing vessel assembly 330. The mixing vessel assembly 330 is capable of heating the lithium and Group-IV nanoparticles to produce the pre-lithiated Group-IV alloy-type nanoparticles.

In some embodiments, the system 300 further includes a deposition source module 340. The deposition source module 340 is configured to deposit the pre-lithiated Group-IV alloy-type nanoparticles over a substrate. In some embodiments, the mixing vessel assembly 330 is fluidly coupled with the deposition source module 340. The mixing vessel assembly 330 can supply the pre-lithiated Group-IV alloy-type nanoparticles to the deposition source module 340. In other embodiments, the pre-lithiated Group-IV alloy-type nanoparticles can be produced in the mixing vessel assembly 330 and stored for later use in either the deposition source module 340 or another deposition source.

The system 300 can further include a system controller 350. The system controller 350 is operable to control various aspects of the system 300. The system controller 350 facilitates the control and automation of the system 300 and can include a central processing unit (CPU), memory, and support circuits (or I/O). Software instructions and data can be coded and stored within the memory for instructing the CPU. The system controller 350 can communicate with one or more of the components of the system 300 via, for example, a system bus. A program (or computer instructions) readable by the system controller 350 determines which tasks are performable on a substrate. In some embodiments, the program is software readable by the system controller 350, which can include code for mixing the various components of the pre-lithiated Group-IV alloy-type nanoparticles. Although the system controller 350 is shown as a single system controller, it should be appreciated that multiple system controllers can be used with the aspects described herein.

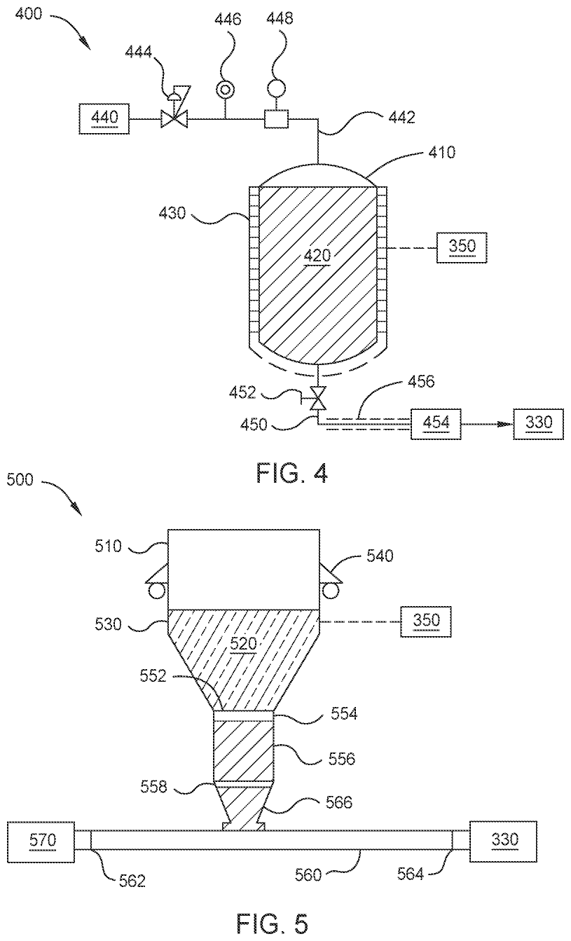

FIG. 4 illustrates a schematic view of one example of a lithium source system 400 according to one or more embodiments. The lithium source system 400 can be used in the lithium source module 310 for supplying lithium to a mixing vessel assembly, for example, the mixing vessel assembly 330. The lithium source system 400 includes a lithium supply tank 410 for holding and supplying lithium. The lithium supply tank 410 contains a supply of lithium 420. In one example, the supply of lithium 420 is in liquid form. In another example, the supply of lithium 420 is in solid form, which is heated to above the melting point of lithium to form liquid lithium prior to delivery to the mixing vessel assembly 330.

The lithium supply tank 410 includes a temperature control device 430, for example, a heating source for melting lithium to form the lithium 420 in molten phase. In one embodiment, the lithium supply tank 410 is positioned on the temperature control device 430, which is adapted to control the temperature of the lithium supply tank 410. For example, in at least one aspect where lithium is supplied in solid form, the temperature control device 430 applies heat to the solid lithium sufficient to melt the solid lithium. Any suitable temperature control device sufficient operable to control the temperature of the lithium supply tank 410 can be used in the temperature control device 430. Examples of temperature control devices include heat exchangers, resistive heaters, temperature control jackets, or any combination thereof.

In some embodiments, the temperature control device 430 is a temperature control jacket operable to control the temperature of the lithium supply tank 410. The temperature control jacket can surround and be in thermal connection with the lithium supply tank 410. In one example, the temperature control jacket is configured as a double walled cylindrical structure defining a passage between the walls for channeling a heated or cooled liquid. A thermocouple can be coupled to at least one of the temperature control jacket and/or the lithium supply tank 410 to provide feedback to a controller, for example, the system controller 350. A flow control mechanism can be provided for changing a flow rate of the heated or cooled liquid through the temperature control jacket based upon a temperature reading received through feedback from the thermocouple. Other heating sources can be used with the lithium supply tank 410. For example, a resistive heater can be thermally coupled or in thermal contact with the lithium supply tank 410 for controlling the temperature of the lithium supply tank 410.

In some embodiments, the lithium source system 400 further includes an inert gas supply 440 that is fluidly coupled with the lithium supply tank 410. In the embodiment shown in FIG. 4, the inert gas supply 440 is fluidly coupled with the lithium supply tank 410 via a first conduit 442, for example, an air hose or pipe. In operation, a pump evacuates air from the lithium supply tank 410, which may be replaced by an inert gas, for example, argon gas, from the inert gas supply 440 to provide a controlled non-reactive environment for the lithium metal within the lithium supply tank 410.

In some embodiments, the lithium source system 400 further includes a pressure regulator 444, for example, a control valve. The pressure regulator 444 is configured to receive inert gas from the inert gas supply 440 via the first conduit 442. The pressure regulator 444 operates to mitigate pressure spikes from the inert gas supply 440. The pressure regulator 444 can be defined by a target pressure regulator pressure. In some embodiments, the pressure regulator 444 is configured to provide inert gas to the first conduit 442 at a pressure that is less than or equal to the target pressure regulator pressure. In other embodiments, the pressure regulator 444 is configured to provide inert gas to the first conduit 442 at a pressure that is greater than or equal to the target pressure regulator pressure. In some embodiments, the pressure regulator 444 is a two-stage pressure regulator. In some embodiments, the pressure regulator 444 is electronically coupled to or electrically communicable with the system controller 350. The system controller 350 may be configured to instruct the pressure regulator 444 to change the target pressure regulator pressure. In this way, the system controller 350 is configured to control the pressure regulator 444.

In some embodiments, the lithium source system 400 further includes a mass flow meter 448, for example, a mass flow sensor, a mass air flow (MAF) sensor, or a MAF meter. The mass flow meter 448 is configured to determine (e.g., sense, acquire, etc.) a mass flow rate of the inert gas passing through the mass flow meter 448. The mass flow meter 448 is electronically coupled to or electrically communicable with the system controller 350. The system controller 350 is configured to receive the mass flow rate from the mass flow meter 448. The mass flow rate may be provided by the system controller 350 for comparison against a target mass flow rate. The system controller 350 can instruct the inert gas supply 440 and/or the pressure regulator 444 based on the mass flow rate received from the mass flow meter 448. In some embodiments, the mass flow meter 448 is a 1,000 liter per minute mass flow meter, for example, the mass flow meter 448 is capable of measuring mass flow rates of up to 1,000 liters per minute.

In some embodiments, the first conduit 442 provides the inert gas to a gauge 446, for example, a pressure gauge. The gauge 446 is configured to determine the pressure of the inert gas in the first conduit 442, and therefore the pressure of the inert gas in the first conduit 442 at a location downstream of the pressure regulator 444. In some embodiments, the gauge 446 is configured to determine gauge pressure (e.g., pressure relative to atmospheric pressure, etc.) and includes an atmospheric input (not shown). The gauge 446 is electronically coupled to or electrically communicable with the system controller 350. The system controller 350 is configured to receive the pressure of the air in the first conduit 442 at a location downstream of the pressure regulator 444 from the gauge 446. The system controller 350 can instruct the inert gas supply 440, the mass flow meter 448, and/or the pressure regulator 444 based on the pressure received from the gauge 446.

In some embodiments, the lithium supply tank 410 is fluidly coupled with the mixing vessel assembly 330 via a second conduit 450. The second conduit 450 conveys molten lithium from the lithium supply tank 410 to the mixing vessel assembly 330. The lithium source system 400 can further include one or more shut-off valves 452 for controlling the flow of molten lithium from the lithium supply tank 410 to the mixing vessel assembly 330. The one or more shut-off valves 452 can be ceramic-lined valves. The system controller 350 can instruct the one or more shut-off valves 452.

In some embodiments, the second conduit 450 further includes a filter assembly 454 operable to remove impurities from the stream of molten lithium flowing through the second conduit 450. The filter assembly 454 can be any design and/or material suitable for removal of unwanted quantities of solid and gaseous contaminants (e.g., lithium nitrides and lithium oxides) from the molten lithium. In one example, the filter assembly 454 includes a skimmer device operable to remove solid contaminants from the surface of the liquid lithium.

In some embodiments, the second conduit 450 further includes a temperature control device 456. The temperature control device 456 maintains the lithium in liquid form in the second conduit 450. Any suitable temperature control device operable to control the temperature of the lithium in the second conduit 450 can be used as the temperature control device 430. In one example, the temperature control device 456 is a temperature control jacket. The temperature control jacket can surround and be in thermal connection with the second conduit 450. In one example, the temperature control jacket is configured as a double walled cylindrical structure defining a passage between the walls for channeling a heated or cooled liquid. A thermocouple can be coupled to at least one of the temperature control jacket and/or the second conduit 450 to provide feedback to a controller, for example, the system controller 350. A flow control mechanism can be provided to control the temperature of the second conduit 450. The flow control mechanism changes a flow rate of the heated or cooled liquid through the temperature control jacket based upon a temperature reading received through feedback from the thermocouple.

FIG. 5 illustrates a schematic view of another example of a lithium source system 500 according to one or more embodiments. The lithium source system 500 can be used in the lithium source module 310 for supplying solid lithium, for example, lithium powder, to the mixing vessel assembly 330. The lithium source system 500 includes a vessel 510 for holding and supplying lithium. The lithium source system 500 further includes a delivery conduit 560 for delivering the lithium 520 to a mixing vessel assembly, for example, the mixing vessel assembly 330. The delivery conduit 560 is fluidly coupled with an inert gas supply 570 at a first end 562 and the mixing vessel assembly 330 at a second end 564.

The vessel 510 contains a supply of lithium 520. In one example, the lithium 520 is in powder form. The vessel 510 has a conical hopper portion 530. The conical hopper portion 530 has a cone angle and forms a lower section of the vessel 510. In some embodiments, a load cell apparatus 540 is used on the vessel 510, which can provide continuous monitoring of the weight of lithium powder in the vessel. The load cell apparatus 540 is electronically coupled to or electrically communicable with the system controller 350. The conical hopper portion 530 leads to a discharge opening 552. The discharge opening 552 is provided with a discharge valve 554 for selectively opening or closing the discharge opening 552. The discharge opening 552 leads to a discharge conduit 556. The discharge conduit 556 is provided with an isolation valve 558. The discharge conduit 556 is coupled with a conical portion 566, which is connected with delivery conduit 560. In operation, an amount of solid lithium can be metered from the conical hopper portion 530 into the discharge conduit 556 by closing the isolation valve 558 and opening the discharge valve 554. The amount of solid lithium can be delivered into the delivery conduit 560 by opening the isolation valve 558. Inert gas supplied from the inert gas supply 570 can be used to deliver the amount of solid lithium into the mixing vessel assembly 330 via the delivery conduit 560.

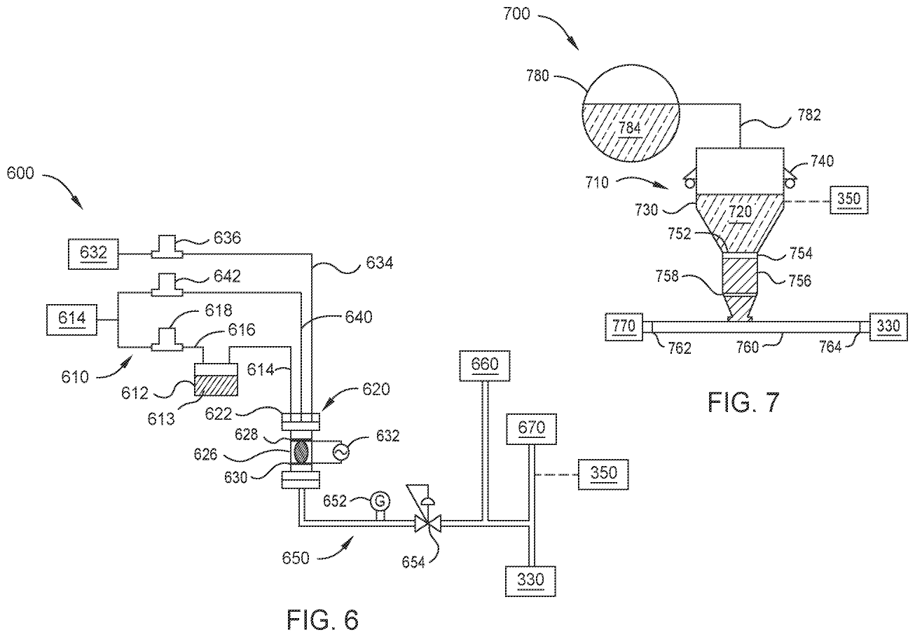

FIG. 6 illustrates a schematic view of one example of a Group-IV nanoparticle source system 600 according to one or more embodiments. The Group-IV nanoparticle source system 600 can be used in the Group-IV nanoparticle source module 320 for supplying Group-IV nanoparticles, for example, germanium or silicon nanoparticles, to a mixing vessel assembly, for example, the mixing vessel assembly 330. The Group-IV nanoparticle source system 600 is configured for non-thermal plasma synthesis of Group-IV nanoparticles. The Group-IV nanoparticle source system 600 includes a Group-IV nanoparticle precursor supply assembly 610 for supplying a gaseous Group-IV nanoparticle precursor and a plasma chamber 620 for converting the Group-IV nanoparticle precursor into Group-IV nanoparticles. The Group-IV nanoparticle source system 600 further includes a delivery conduit 650 for delivering the Group-IV nanoparticles from the plasma chamber 620 to a mixing vessel assembly, for example, the mixing vessel assembly 330.

In some embodiments, the Group-IV nanoparticle precursor supply assembly 610 includes a liquid solution bubbler 612 fluidly coupled with a push gas source or a first carrier gas source 614. In the embodiments shown in FIG. 6, the first carrier gas source 614 is fluidly coupled with the liquid solution bubbler 612 via a first conduit 616, for example, an air hose or pipe. The first conduit 616 can include a mass flow meter 618, for example, a mass flow sensor, a mass air flow (MAF) sensor, or a MAF meter. The mass flow meter 618 is configured to determine (e.g., sense, acquire, etc.) a mass flow rate of the carrier gas passing through the mass flow meter 618. The mass flow meter 618 is electronically coupled to or electrically communicable with the system controller 350. The first conduit 616 can further include one or more valves for controlling the flow rate of the push gas into the liquid solution bubbler 612. The push gas or the first carrier gas source 614 can include an inert gas, for example argon gas.

The liquid solution bubbler 612 typically contains a liquid Group-IV nanoparticle precursor 613. The liquid Group-IV nanoparticle precursor 613 can be a Group-IV chloride. The Group-IV chloride can be, for example, GeCl₄, CCl₄, SnCl₄, or SiCl₄. In one example, the Group-IV chloride is a GeCl₄ solution. In one example a push gas such as argon, which is supplied by the first carrier gas source 614 is bubbled through the liquid Group-IV nanoparticle precursor 613 in the liquid solution bubbler 612. A process gas control subroutine can regulate the flow of the push gas, the pressure in the liquid solution bubbler 612, and temperature of the liquid solution bubbler 612 to obtain the desired Group-IV nanoparticle precursor gas. The desired process gas flow rates can be transferred to a process gas control subroutine as process parameters. The process gas control subroutine can be executed by the system controller 350.

The Group-IV nanoparticle precursor gas can be delivered from the liquid solution bubbler 612 to the plasma chamber 620 via a second conduit 619, for example, an air hose or pipe. The second conduit 619 can be fluidly coupled with a gas distribution assembly 622 of the plasma chamber 620.

The plasma chamber 620 includes a chamber body 624. The gas distribution assembly 622 and the chamber body 624 enclose a plasma region 626. The plasma chamber 620 includes an upper plasma generating electrode 628 and a lower plasma generating electrode 630 for generating a processing plasma in a central portion of the plasma region by transmitting electrical power from an RF power source 633 to the central portion while a gas is present in the plasma region 626. The plasma chamber 620 can further include at least one set of magnets for maintaining a boundary layer plasma in a boundary portion of the plasma region 626 around the processing plasma.

The gas distribution assembly 622 can be fluidly coupled with a hydrogen gas source 632 via a third conduit 634, for example, an air hose or pipe. Hydrogen gas is delivered from the hydrogen gas source 632 into the plasma region 626 via the gas distribution assembly 622. Not to be bound by theory, but it is believed that the hydrogen gas scavenges chlorine that results from the decomposition of the Group-IV chloride. Without hydrogen gas, Group-IV nanoparticles may not form. The third conduit 634 can further include a mass flow meter 636 and one or more valves for controlling the flow rate of the hydrogen gas into the plasma region 626.

In some embodiments, the gas distribution assembly 622 can be fluidly coupled with an inert gas source, for example, the first carrier gas source 614 via a fourth conduit 640, for example, an air hose or pipe. An inert gas, for example, argon is delivered from the first carrier gas source 614 into the plasma region 626 via the gas distribution assembly 622. The inert gas can be used as a plasma-forming gas. The fourth conduit 640 can further include a mass flow meter 642 and one or more valves for controlling the flow rate of the inert gas into the plasma region 626.

The plasma chamber 620 is fluidly coupled with a mixing vessel, for example, the mixing vessel assembly 330. The Group-IV nanoparticle source system 600 further includes a delivery conduit 650 for delivering the Group-IV nanoparticles from the plasma chamber 620 to a mixing vessel, for example, the mixing vessel assembly 330.

In some embodiments, the Group-IV nanoparticle source system 600 further includes a pressure regulator 654, for example, a control valve. The pressure regulator 654 is configured to receive fluidized powder from the plasma chamber 620 via the delivery conduit 650. The pressure regulator 654 operates to mitigate pressure spikes from the fluidized powder flowing from the plasma chamber 620 through the delivery conduit 650. The pressure regulator 654 can be defined by a target pressure regulator pressure. In some embodiments, the pressure regulator 654 is configured to provide fluidized powder to the delivery conduit 650 at a pressure that is less than or equal to the target pressure regulator pressure. In other embodiments, the pressure regulator 654 is configured to provide fluidized powder to the delivery conduit 650 at a pressure that is greater than or equal to the target pressure regulator pressure. In some embodiments, the pressure regulator 654 is a two-stage pressure regulator. In some embodiments, the pressure regulator 654 is electronically coupled to or electrically communicable with the system controller 350. The system controller 350 may be configured to instruct the pressure regulator 654 to change the target pressure regulator pressure. In this way, the system controller 350 is configured to control the pressure regulator 654.

In some embodiments, the Group-IV nanoparticle source system 600 further includes a gauge 652, for example, a pressure gauge. The delivery conduit 650 provides the fluidized powder to the gauge 652. The gauge 652 is configured to determine the pressure of the fluidized powder in the delivery conduit 650, and therefore the pressure of the fluidized powder in the delivery conduit 650 at a location upstream of the pressure regulator 654. In some embodiments, the gauge 652 is configured to determine gauge pressure (e.g., pressure relative to atmospheric pressure, etc.) and includes an atmospheric input (not shown). The gauge 652 can be electronically coupled to or electrically communicable with the system controller 350. The system controller 350 is configured to receive the pressure of the fluidized powder in the delivery conduit 650 at a location upstream of the pressure regulator 654 from the gauge 652. The system controller 350 can instruct the plasma chamber 620 and/or the pressure regulator 654 based on the pressure received from the gauge 652.

In some embodiments, the Group-IV nanoparticle source system 600 further includes a pump 660, for example, a vacuum pump for removal of exhaust gases from the Group-IV nanoparticle source system 600. The pump 660 is fluidly coupled with the delivery conduit 650. The pump 660 can be fluidly coupled with the delivery conduit 650 downstream of the pressure regulator 654 and upstream of the mixing vessel assembly 330.

In some embodiments, the Group-IV nanoparticle source system 600 further includes an inert gas source 670. The inert gas source 670 provides a carrier gas for delivering the fluidized powder to the mixing vessel assembly 330. The inert gas source 670 is fluidly coupled with the delivery conduit 650. The inert gas source 670 can be fluidly coupled with the delivery conduit 650 downstream of the pressure regulator 654 and/or the pump 660 and upstream of the mixing vessel assembly 330.

In operation, the Group-IV nanoparticles are generated by dissociation of the Group-IV chloride in the plasma formed in the plasma region 626 and subsequent clustering of the Group-IV chloride radicals. In one example, argon and hydrogen are used as buffer gases and are supplied to the plasma region 626 by the first carrier gas source 614 and the hydrogen gas source 632 respectively. GeCl₄ is supplied to the plasma region 626 by the liquid solution bubbler 612. Radio frequency power is applied by the RF power source to the upper plasma generating electrode 628 and the lower plasma generating electrode 630 to generate a processing plasma in the plasma region 626 while gas is present in the plasma region 626. The germanium nanoparticles are generated by dissociation of the GeCl₄ in the plasma formed in the plasma region 626 and subsequent clustering of the GeCl₄ radicals. The germanium nanoparticles are then delivered to the mixing vessel assembly 330 via the delivery conduit 650.

FIG. 7 illustrates a schematic view of another example of a Group-IV nanoparticle source system 700 according to one or more embodiments. The Group-IV nanoparticle source system 700 can be used in the Group-IV nanoparticle source module 320 for supplying Group-IV nanoparticles, for example, germanium, tin, carbon, or silicon nanoparticles, to a mixing vessel assembly, for example, the mixing vessel assembly 330. The Group-IV nanoparticle source system 700 is configured to apply a shearing force to Group-IV material to produce Group-IV nanoparticles. The Group-IV nanoparticle source system 700 includes a hopper assembly 710 for holding and supplying Group-IV nanoparticles. The hopper assembly 710 includes a vessel body 712 for holding and supplying Group-IV nanoparticles. The Group-IV nanoparticle source system 700 further includes a delivery conduit 760 for delivering the Group-IV nanoparticles to the mixing vessel assembly 330. The delivery conduit 760 is fluidly coupled with an inert gas supply 770 at a first end 762 and the mixing vessel assembly 330 at a second end 764.

In some embodiments as shown in FIG. 7, the Group-IV nanoparticle source system 700 further includes a ball mill container 780 fluidly coupled with the vessel body 712 via a supply conduit 782. The ball mill container 780 contains a Group-IV material 784. The ball mill container 780 is configured to apply a shearing force to Group-IV material 784 to produce Group-IV nanoparticles 720. The mechanical shearing force can be applied to the Group-IV material 784 by placing the Group-IV material 784 and ball mill balls in the ball mill container 780 and rotating the ball mill container 780 for a predetermined time to allow the ball mill balls to generate friction with a wall of the ball mill container 780 and rotate by themselves. In one example, the rotating of the ball mill container 780 to apply a mechanical shearing force to the Group-IV material 784 is performed in a non-oxidizing atmosphere. In another example, the rotating of the ball mill container 780 to apply a mechanical shearing force to the Group-IV material 784 is performed in an oxidizing atmosphere.

The Group-IV material 784 can be an artificially prepared Group-IV material or a natural Group-IV material. A Group-IV material used in the example can include a plate-type Group-IV material, a powder-type Group-IV material, and a lump Group-IV material, and is not particularly limited to the shape and size thereof.

A material for the ball mill ball is not particularly limited, but a ball mill ball formed of a polyimide material may be used in order to effectively apply a frictional force and prevent excessive damage to the Group-IV material 784. A size of the ball mill ball can be appropriately selected in consideration of a shearing force to be applied to the Group-IV material 784. For example, a diameter of the ball mill ball may be in a range of about 3 mm to about 50 mm. In the case that the size of the ball mill ball is less than 3 mm, a mass of the ball mill ball may be relatively low and thus, a mechanical shearing force exerted on the Group-IV material 784 may be lower than a desired value. In contrast, in the case that the size of the ball mill ball is greater than 50 mm, an excessively high shearing force or impact may be exerted on the Group-IV material 784 and thus, the Group-IV material 784 may be damaged.

A mixing ratio of the Group-IV material 784 and the ball mill balls can be appropriately controlled. For example, in order to apply a mechanical shearing force to the entire Group-IV material 784, the Group-IV material 784 and the ball mill balls can be combined so that the total weight of the ball mill balls is greater than that of the Group-IV material 784.

Thereafter, the ball mill container 780 can be rotated to allow the ball mill balls introduced in the ball mill container 780 to apply a mechanical shearing force to the Group-IV material 784.

In one example, the inside of the ball mill container 780 can be maintained in a non-oxidizing atmosphere during a ball milling process in order to prevent the Group-IV material 784 from oxidation during the ball milling process. For example, in order to prevent the Group-IV material 784 from oxidation, the inside of the ball mill container can be maintained in a non-oxidizing atmosphere by purging with argon gas after being maintained in a vacuum.

The vessel body 712 contains a supply of the Group-IV nanoparticles 720. In one example, the Group-IV nanoparticles 720 are in powder form. The vessel body 712 has a conical hopper portion 730. The conical hopper portion 730 has a cone angle and forms a lower section of the vessel body 712. In some embodiments, a load cell apparatus 740 is used on the vessel body 712, which can provide continuous monitoring of the weight of the Group-IV nanoparticles 720 in the vessel body 712. The load cell apparatus 740 is electronically coupled to or electrically communicable with the system controller 350. The conical hopper portion 730 leads to a discharge opening 752. The discharge opening 752 is provided with a discharge valve 754 for selectively opening or closing the discharge opening 752. The discharge opening 752 leads to a discharge conduit 756. The discharge conduit 756 is provided with an isolation valve 758. The discharge conduit 756 is coupled with a conical portion 766, which is connected with the delivery conduit 760. In operation, an amount of the Group-IV nanoparticles 720 can be metered from the conical hopper portion 730 into the discharge conduit 756 by closing the isolation valve 758 and opening the discharge valve 754. The amount the Group-IV nanoparticles 720 can be delivered into the delivery conduit 760 by opening the isolation valve 758. Inert gas supplied from the inert gas supply 770 can be used to deliver the amount of Group-IV nanoparticles 720 into the mixing vessel assembly 330.

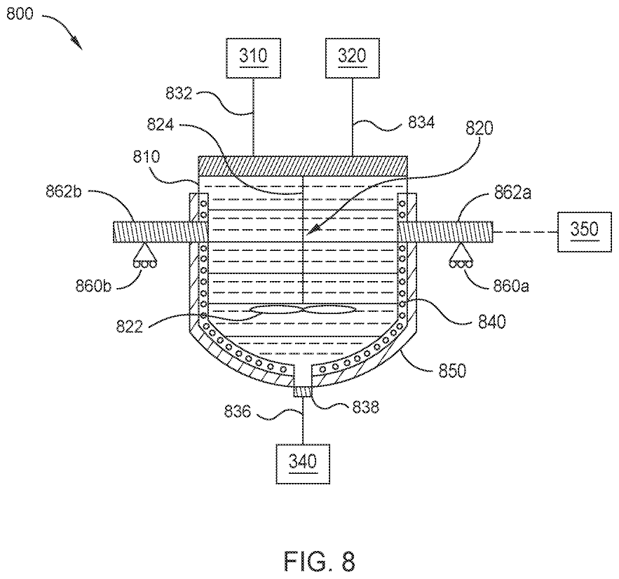

FIG. 8 illustrates a schematic view of a mixing vessel assembly 800 according to one or more embodiments. The mixing vessel assembly 800 can be used as the mixing vessel assembly 330 depicted in FIG. 3. The mixing vessel assembly 800 is configured for mixing Group-IV nanoparticles and lithium to form lithiated Group-IV alloy type nanoparticles. The mixing vessel assembly 800 can be a rotary-type mixer. The mixing vessel assembly 800 includes a mixing vessel container 810 for holding and mixing the Group-IV nanoparticles with lithium.

A stirring member 820 is positioned in the mixing vessel container 810. Any suitable stirring member that provides for sufficient mixing, for example, homogeneous mixing of the Group-IV nanoparticles with lithium, can be used. In one example, the stirring member 820 employed includes a first impeller 822 or one dispersing device of rotor/stator type with a variable rotational speed. The variable speed makes it possible to adjust the tip speed of the first impeller 822 and thus the mixing of the Group-IV nanoparticles with the lithium. The first impeller 822 is coupled with a shaft 824. The stirring member 820 can further include a second impeller that has a pumping action for high axial displacement to reduce mixing time. In some embodiments, the first impeller and the second impeller are both positioned on the shaft 824.

The mixing vessel assembly 800 further includes a first delivery conduit 832 for delivering lithium from the lithium source module 310 to the mixing vessel container 810. The mixing vessel assembly 800 further includes a second delivery conduit 834 for delivering Group-IV nanoparticles from the Group-IV nanoparticle source module 320 to the mixing vessel container 810. The delivery conduit 760 is fluidly coupled with an inert gas supply 770 at a first end 762 and the mixing vessel assembly 330 at a second end 764. The mixing vessel assembly 800 further includes an outlet conduit 836 for delivering the lithiated Group-IV alloy type nanoparticles from the mixing vessel assembly 800 to the deposition source module 340. An outlet valve 838 can be positioned along the outlet conduit 836 to control the flow of the lithiated Group-IV alloy type nanoparticles.

The mixing vessel assembly 800 includes a temperature control device 840, for example, a heating source for alloying the lithium with the Group-IV nanoparticles. The temperature control device 840 can surround and be in thermal connection with the mixing vessel container 810. In one or more embodiments, the mixing vessel container 810 is positioned on the temperature control device 840, which is adapted to control the temperature of the mixing vessel container 810. For example, the temperature control device 840 applies sufficient heat to alloy the lithium with the Group-IV nanoparticles. Any suitable temperature control device sufficient to control the temperature of the mixing vessel container 810 can be used in the temperature control device 840. Examples of temperature control devices include heat exchangers, resistive heaters, temperature control jackets, or any combination thereof.

In other embodiments, the temperature control device 840 is a temperature control jacket operable to control the temperature of the mixing vessel container 810. The temperature control jacket can surround and be in thermal connection with the mixing vessel container 810. In one example, the temperature control jacket can be configured as a double walled cylindrical structure defining a passage between the walls for channeling a heated or cooled liquid. A thermocouple can be coupled to at least one of the temperature control jacket and/or the mixing vessel container 810 to provide feedback to a controller, for example, the system controller 350. A flow control mechanism can be provided for changing a flow rate of the heated or cooled liquid through the temperature control jacket based upon a temperature reading received through feedback from the thermocouple. Other heating sources can be used with the mixing vessel container 810. For example, a resistive heater can be thermally coupled or in thermal contact with the mixing vessel container 810 for controlling the temperature of the mixing vessel container 810.

The mixing vessel assembly 800 can further include insulation 850. The insulation can surround and be in thermal contact with the temperature control device 840.

In some embodiments, the mixing vessel assembly 800 can further include one or more load cells 860a, 860b (collectively 860). The one or more load cells 860 can be secured to the mixing vessel container 810 by a load cell mount 862a, 862b (collectively 862) or another suitable means. The one or more load cells 860 are designed to measure the force applied thereto and provide an output value (signal) representative of the force measured. This output value can then be utilized as is, in terms of force on the load cell 860, or the output value can be converted to reflect the resultant torque about the shaft 824, using various known component parameters. The output value can then be used as an input signal to control functions of the system such as, for example, mixing speed, delivery of additional lithium and Group-IV nanoparticles into the mixing vessel container 810, and/or delivery of lithiated Group-IV alloy type nanoparticles from the mixing vessel container 810.

In some embodiments, the lithium and the Group-IV nanoparticles are delivered to the mixing vessel container 810 sequentially. In one example, a first layer of lithium is delivered into the mixing vessel container 810 via the first delivery conduit 832 and a second layer of Group-IV nanoparticles is deposited on the first layer of lithium via the second delivery conduit 834. These operation can be repeated sequentially until a targeted amount of alternating layers of lithium metal and Group-IV nanoparticles is present in the mixing vessel container 810. Not to be bound by theory but it has been found by the inventors that alternating layers of lithium metal and Group-IV nanoparticles for a more homogenous mixture when mixed.

In some embodiments, lithium-alloy nanoparticles, for example, Li₂₂Ge₅, are obtained from a metallurgical alloying process in which molten lithium and Group-IV nanoparticles are introduced into the mixing vessel container 810. Group-IV nanoparticles are obtained from non-thermal plasma synthesis of a Group-IV-halide source. Both lithium and Group-IV nanoparticles are added in sequencing layers to reduce alloying time. After the process is complete, the particles can be mixed in a slurry form with, for example, carbon black, a binder, and a solvent, to be casted using traditional slurry-based methods, for example, slot-die coating. Alternatively, the Group-IV nanoparticles serve as stable lithium-carrying reagent and are applied onto a graphite-coated current collector using traditional powder coating methods and optionally calendaring with heat for adhesion.

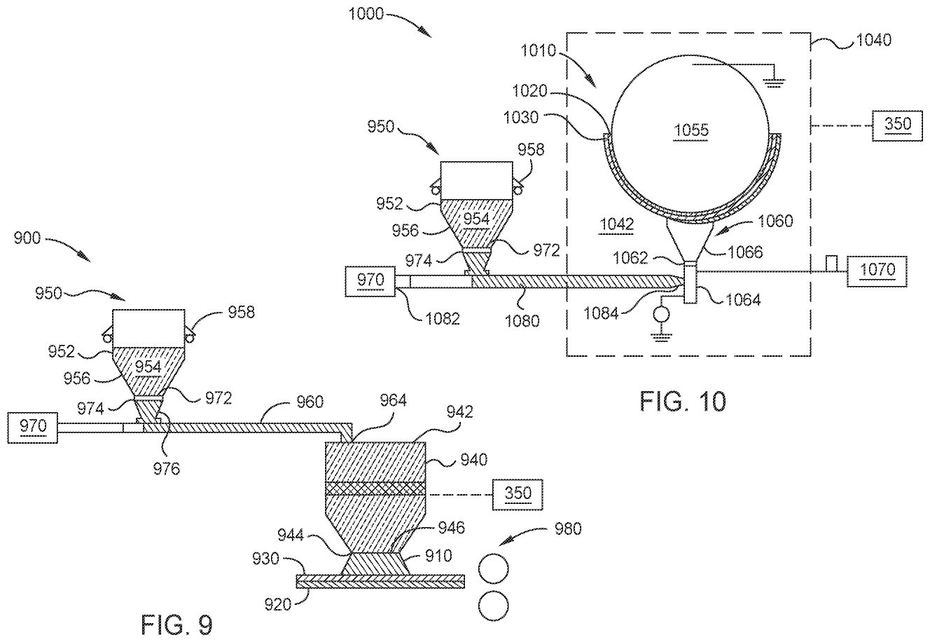

FIG. 9 illustrates a schematic view of one example of a deposition source module 900 according to one or more embodiments. The deposition source module 900 can be used as the deposition source module 340 depicted in FIG. 3. The deposition source module 900 is configured for depositing lithiated Group-IV alloy type nanoparticles over a flexible substrate, for example, an anode structure 910. In one example, the anode structure 910 includes a current collector 920 having a graphite-containing anode 930 formed thereon.

In some embodiments, the deposition source module 900 includes a sifter body 940. The sifter body 940 includes a sifter body open top end 942 and a sifter body bottom end 944, which terminates in a sifter 946. In one example, the sifter body 940 is conical in shape. The sifter body 940 defines a sifter body interior for holding the lithiated Group-IV alloy type nanoparticles. The sifter 946 has a plurality of openings at the sifter body bottom end 944. The plurality of openings regulate the amount of material capable of being deposited over the anode structure 910. The material to be dispensed is stored within the interior space defined by the sifter body 940.

The deposition source module 900 can further include a hopper assembly 950 for storing and supplying lithiated Group-IV alloyed nanoparticles, for example, lithiated silicon or germanium nanoparticles, to the sifter body 940. The hopper assembly 950 includes a vessel body 952 for holding and supplying the lithiated Group-IV alloy type nanoparticles lithiated. The deposition source module 900 can further include a delivery conduit 960 for delivering the lithiated Group-IV alloy type nanoparticles to the sifter body 940. The delivery conduit 960 is fluidly coupled with an inert gas supply 970 at a first end 962 and the mixing vessel assembly 330 at a second end 964.

The vessel body 952 contains a supply of the lithiated Group-IV alloy type nanoparticles 954. The vessel body 952 has a conical hopper portion 956. The conical hopper portion 956 has a cone angle and forms a lower section of the vessel body 952. In some embodiments, a load cell apparatus 958 is used on the vessel body 952. The load cell apparatus 958 can provide continuous monitoring of the weight of the lithiated Group-IV alloy type nanoparticles 954 in the vessel body 952. The load cell apparatus 958 is electronically coupled to or electrically communicable with the system controller 350. The conical hopper portion 956 leads to a discharge opening 972. The discharge opening 972 is provided with a discharge valve 974 for selectively opening or closing the discharge opening 972. The discharge opening 972 leads to a discharge conduit 976. In one example, the discharge conduit 976 has a conical shape. In operation, an amount of the lithiated Group-IV alloy type nanoparticles 954 can be metered from the conical hopper portion 956 into the discharge conduit 976 by opening the discharge valve 974. The lithiated Group-IV nanoparticles can be delivered into the delivery conduit 960 by opening the discharge valve. Inert gas supplied from the inert gas supply 970 can be used to deliver an amount of the lithiated Group-IV alloy type nanoparticles 954 to the sifter body 940.

The deposition source module 900 can further include a set of calendering rollers 980 for activating the lithiated Group-IV nanoparticles. The calendering rollers 980 can be temperature controlled.

FIG. 10 illustrates a schematic view of another example of a deposition source system 1000 according to one or more embodiments. The deposition source system 1000 can be used as the deposition source module 340 depicted in FIG. 3. The deposition source system 1000 is configured for depositing lithiated Group-IV alloy type nanoparticles over a flexible substrate, for example, an anode structure 1010. In one example, the anode structure 1010 includes a current collector 1020 having a graphite-containing anode 1030 formed thereon.

In some embodiments, the deposition source system 1000 includes a processing module 1040, which defines a vacuum processing environment 1042 according to one or more embodiments. The deposition source system 1000 can be a flexible substrate coating system, for example, a SMARTWEB® system manufactured by Applied Materials, adapted for manufacturing lithium-containing anode film stacks according to the embodiments described herein. The deposition source system 1000 can be used for manufacturing pre-lithiated anode structures, and particularly for film stacks for pre-lithiated anode structures. The deposition source system 1000 is constituted as a roll-to-roll system including the processing module 1040. The deposition source system 1000 can further include an unwinding module and a winding module. In some embodiments, the processing module 1040 includes a plurality of processing modules or chambers arranged in sequence, each configured to perform one processing operation to a continuous sheet of material, for example, the current collector 1020 or web of material.

In some embodiments, the processing chambers can be radially disposed about a coating drum 1055. The coating drum 1055 can be temperature controlled. Although the processing module 1040 has a single deposition source 1060, the processing module 1040 can be divided into two or more sub-modules each including a separate deposition source. In one or more embodiments as shown in FIG. 10, the deposition source 1060 is an electrospray gun 1064. In one example, the electrospray gun 1064 is a triboelectric powder spray gun. In another example, the electrospray gun 1064 is a corona spray gun. The electrospray gun 1064 or head charges the lithiated Group-IV alloy type nanoparticles, and the charged lithiated Group-IV nanoparticles 1066 are emitted from a nozzle 1062 of the electrospray gun 1064. The charged lithiated Group-IV nanoparticles 1066 move toward the anode structure 1010, which is transferred by the coating drum 1055. The electrospray gun 1064 can be fluidly coupled with an inert gas source 1070.

The deposition source system 1000 can further include a hopper assembly for storing and supplying lithiated Group-IV alloyed nanoparticles, for example, lithiated silicon or germanium nanoparticles, to the electrospray gun 1064. The hopper assembly can be the hopper assembly 950 described in FIG. 9. The deposition source system 1000 can further include a delivery conduit 1080 for delivering the lithiated Group-IV alloyed nanoparticles from the hopper assembly to the electrospray gun 1064. The delivery conduit 1080 is fluidly coupled with the inert gas supply 970 at a first end 1082 and the electrospray gun 1064 at a second end 1084.

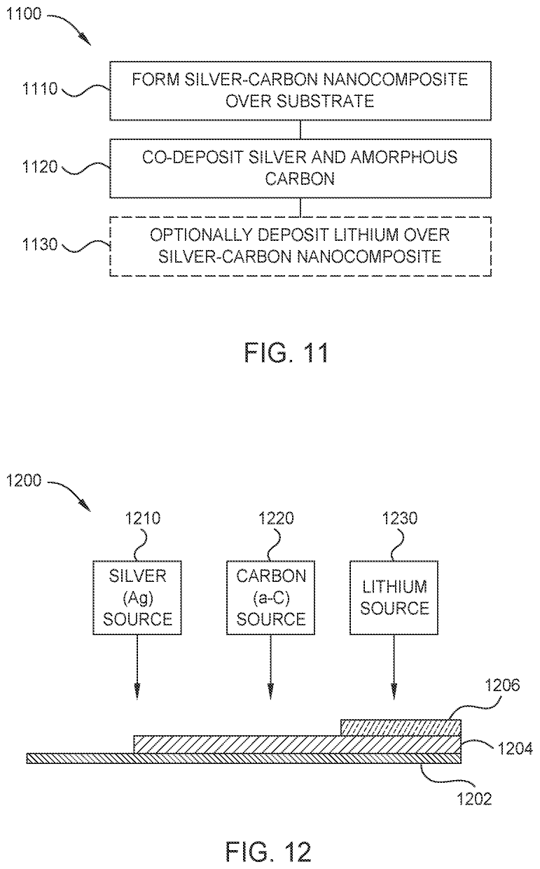

FIG. 11 illustrates a process flow chart 1100 summarizing one or more embodiments of a method of forming a silver-carbon (Ag—C) nanocomposite according to one or more embodiments. FIG. 12 illustrates a schematic view of a system 1200 for forming a silver-carbon (Ag—C) nanocomposite according to one or more embodiments. The method depicted in the process flow chart 1100 of FIG. 11 can be performed on the system 1200 depicted in FIG. 12. The silver-carbon (Ag—C) nanocomposite can be a lithium metal-free silver carbon (“Ag—C”) nanocomposite. The silver-carbon nanocomposite can be deposited utilizing silver (PVD) and carbon (PECVD) co-deposition to make anode coatings that can regulate Li nucleation energy to minimize dendrites is provided. The silver deposition can be performed via a PVD process. The carbon deposition can be performed via a chemical vapor deposition, for example, a plasma-enhanced chemical vapor deposition (PECVD) process.

At operation 1110, a silver-carbon nanocomposite is formed over a substrate. The silver-carbon nanocomposite can function as an electrode, for example, an anode. The silver-carbon nanocomposite can be silver-carbon nanocomposite layer 1204. The substrate can be substrate 1202. The substrate 1202 can be a continuous flexible substrate, for example, the continuous flexible substrate 110 described in FIG. 1. In one example, the substrate 1202 includes a conductive material, typically a metal, such as copper (Cu) or nickel (Ni).

Operation 1110 includes operation 1120. At operation 1120, silver and carbon, for example, amorphous carbon, are co-deposited to form a silver-carbon nanocomposite layer, such as the silver-carbon nanocomposite layer 1204. The silver can be deposited using a silver (Ag) source 1210 and the carbon can be deposited using a carbon source 1220.

The silver (Ag) source 1210 can be a sputtering source. Examples of sputtering sources include magnetron sputter sources, DC sputter sources, for example, a DC sputtering gun, AC sputter sources, pulsed sputter sources, radio frequency (RF) sputtering sources, or middle frequency (MF) sputtering sources. For instance, MF sputtering with frequencies in the range of 5 kHz to 100 kHz, for example, 30 kHz to 50 kHz, can be provided. As used herein, “magnetron sputtering” refers to sputtering performed using a magnet assembly, that is, a unit capable of a generating a magnetic field. Typically, such a magnet assembly includes a permanent magnet. This permanent magnet is typically arranged within a rotatable target or coupled to a planar target in a manner such that the free electrons are trapped within the generated magnetic field generated below the rotatable target surface. Such a magnet assembly may also be arranged coupled to a planar cathode.

The carbon source 1220 can be a plasma-enhanced chemical vapor deposition (PECVD) source. Precursor gases that can be used to form the carbon portion of the silver-carbon nanocomposite include hydrocarbon gases and hydrogen. In one example, the carbon portion of the silver-carbon nanocomposite is an amorphous carbon film. The hydrocarbon gases can include hydrogen compounds with the general formula CₓH_{y} where x has a range of 1 and 10 and y has a range of 2 and 22. For example, methane (CH₄), acetylene (C₂H₂), propylene (C₃H₆), propyne (C₃H₄), propane (C₃H₈), butane (C₄H₁₀), butylene (C₄H₈), butadiene (C₄H₆), pentane, pentene, pentadiene, cyclopentane, cyclopentadiene, benzene, toluene, alpha terpinene, phenol, cymene, norbornadiene, as well as combinations thereof, may be used as the hydrocarbon compound. Similarly, a variety of gases such as hydrogen (H₂), nitrogen (N₂), ammonia (NH₃), or combinations thereof, among others, can be added to the gas mixture, if desired. Argon (Ar), helium (He), and nitrogen (N₂) can be used to control the density and deposition rate of the carbon portion.

In some embodiments, during deposition of the carbon portion, the substrate is maintained at a temperature from about 200 degrees Celsius to about 700 degrees Celsius, for example, from about 250 degrees Celsius to about 350 degrees Celsius, such as about 300 degrees Celsius. In some embodiments, an RF power level of from about 20 W to about 1,600 W, for example, about 1,000 W. The RF power can be provided at a frequency from about 0.01 MHz to about 300 MHz, for example, 13.56 MHz. In some embodiments, the RF power can be provided to a gas distribution assembly or “showerhead” electrode in the carbon source 1220. In some embodiments, the RF power may be provided at a mixed frequency, such as at a high frequency of about 13.56 MHz and a low frequency of about 350 kHz. The RF power may be cycled or pulsed and continuous or discontinuous.

Optionally, at operation 1130, a lithium layer is deposited over the silicon-carbon nanocomposite. The lithium layer can function as a pre-lithiation layer, which replenishes lithium lost from first cycle capacity loss of the silicon-carbon nanocomposite. The lithium layer can be lithium layer 1206 depicted in FIG. 12. The lithium layer can be deposited by a lithium source such as the lithium source 1230. The lithium layer 1206 can be a thin lithium metal film (e.g., 20 microns or less, from about 1 micron to about 20 microns, from about 2 microns to about 10 microns). The lithium source 1230 can include an evaporation system, such as an electron-beam evaporator, a thermal evaporator, or a thin film transfer system (including large area pattern printing systems such as gravure printing systems), a lamination system, or a slot-die deposition system.

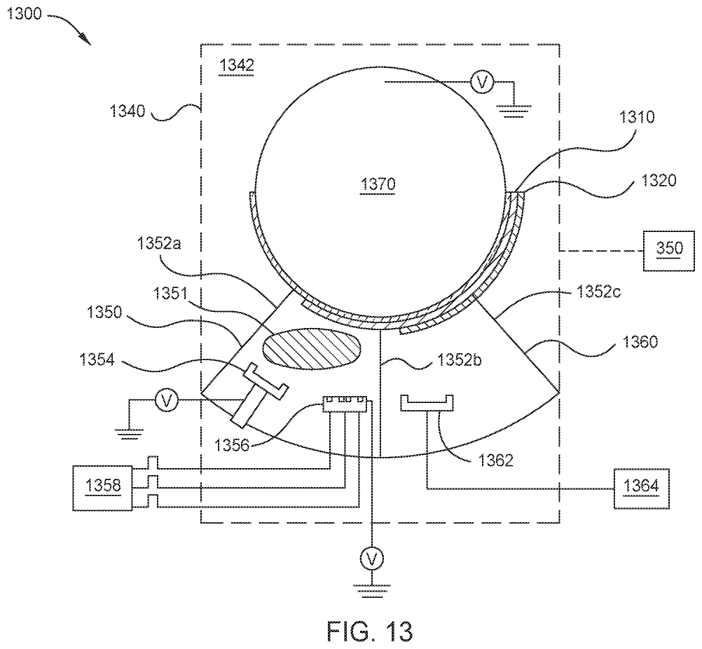

FIG. 13 illustrates a schematic view of another deposition source system 1300 for forming a silver-carbon (Ag—C) nanocomposite according to one or more embodiments. The deposition source system 1300 is configured for depositing a film stack including a silver-carbon (Ag—C) nanocomposite layer 1310 and optionally a lithium layer 1320 over a substrate 1330, for example, a flexible continuous substrate or web of material. In one example, the substrate 1330 is a current collector as described and disclosed herein. In another example, the substrate 1330 includes a current collector having an anode formed thereon.

In some embodiments, the deposition source system 1300 includes a processing module 1340, which defines a vacuum processing environment 1342. The deposition source system 1300 can be a flexible substrate coating system, for example, a SMARTWEB® system manufactured by Applied Materials, adapted for manufacturing anode film stacks according to the embodiments described herein. The deposition source system 1300 can be used for manufacturing silver carbon anode structures, and particularly for pre-lithiated anode structures. The deposition source system 1300 is constituted as a roll-to-roll system including the processing module 1340. The deposition source system 1300 can further includes an unwinding module for supplying the substrate 1330 and a winding module for collecting the pre-lithiated silver-carbon anode structure. In some embodiments, the processing module 1340 includes a plurality of processing modules or sub-chambers arranged in sequence, each configured to perform one processing operation to a continuous sheet of material, for example, the substrate 1330 or web of material.

In some embodiments, the processing module 1340 includes a plurality of processing modules or first and second sub-chambers 1350 and 1360 arranged in sequence, each configured to perform one processing operation to the substrate 1330. In one example, as depicted in FIG. 13, the first and second sub-chambers 1350 and 1360 are radially disposed about a coating drum 1370. The coating drum 1370 can be temperature controlled. The first and second sub-chambers 1350 and 1360 are separated by partition walls 1352a-1352c (collectively 1352). For example, the first sub-chamber 1350 is defined by partition walls 1352a and 1352b and the second sub-chamber 1360 is defined by partition walls 1352b and 1352c. In one example, the first and second sub-chambers 1350 and 1360 are closed with the exception of narrow, arcuate gaps defined by partition walls 1352 and facing the coating drum 1370. A plasma region 1352 can be generated and/or contained within the first sub-chamber 1350.

The first and second sub-chambers 1350 and 1360 typically include one or more deposition sources 1354, 1356, and 1362. Generally, the one or more deposition sources 1354, 1356, and 1362 as described and disclosed herein include a sputtering source and additional sources, which can be selected from the group of CVD sources, PECVD sources, and various evaporation sources. In some embodiments, the deposition source 1354 is a sputtering source configured to deposit silver, for example, a silver portion of the silver-carbon (Ag—C) nanocomposite layer 1310. Examples of sputtering sources include magnetron sputter sources, DC sputter sources, AC sputter sources, pulsed sputter sources, radio frequency (RF) sputtering sources, or middle frequency (MF) sputtering sources. For instance, MF sputtering with frequencies in the range of 5 kHz to 100 kHz, for example, 30 kHz to 50 kHz, can be provided. As used herein, “magnetron sputtering” refers to sputtering performed using a magnet assembly, that is, a unit capable of a generating a magnetic field. Typically, such a magnet assembly includes a permanent magnet. This permanent magnet is typically arranged within a rotatable target or coupled to a planar target in a manner such that the free electrons are trapped within the generated magnetic field generated below the rotatable target surface. Such a magnet assembly may also be arranged coupled to a planar cathode.

In some embodiments, the second deposition source 1356 is a chemical vapor deposition source configured to deposit carbon, for example, a carbon portion of the silver-carbon (Ag—C) nanocomposite layer 1310. In one example, the second deposition source 1356 is a plasma-enhanced chemical vapor deposition (PECVD) source. The second deposition source 1356 can be fluidly coupled with a gas panel 1358 configured to deliver precursor gases to the second deposition source 1356. In some embodiments, the gas panel 1358 includes hydrocarbon gas source, inert gas source, and hydrogen gas source. In one example, the hydrocarbon gas source includes methane, the inert gas source includes argon, and the hydrogen gas source includes hydrogen.

The one or more deposition sources 1354, 1356, and 1362 can include one or more evaporation sources. In some embodiments, the third deposition source 1362 is an evaporation source fluidly coupled with a lithium source 1364. The third deposition source 1362 can be configured to deposit lithium, for example, lithium layer 1320. Examples of evaporation sources include thermal evaporation sources and electron beam evaporation sources. In one example, the evaporation source is a thermal evaporation source configured to deposit lithium. The material to be deposited (e.g., lithium) can be provided in a crucible. The lithium can, for example, be evaporated by thermal evaporation techniques or by electron beam evaporation techniques.

The first sub-chamber 1350 includes the first deposition source 1354 and the second deposition source 1356. In the embodiment depicted in FIG. 1, the first deposition source 1354 is a DC sputtering gun and the second deposition source 1356 is an electrode showerhead. The first deposition source 1354 can be configured to deposit silver by a sputtering process. The second deposition source 1356 can be configured to deposit a carbon material, for example, an amorphous carbon material by a PECVD process. The first deposition source 1354 and the second deposition source 1356 can be configured to co-deposit silver and carbon to form the silver-carbon (Ag—C) nanocomposite layer 1310. The second sub-chamber 1360 includes a third deposition source 1362. The third deposition source 1362 can be an evaporation source, for example, a thermal evaporation source. The third deposition source 1362 is configured to deposit the lithium layer 1320 over the silver-carbon (Ag—C) nanocomposite layer 1310.

The first and second sub-chambers 1350 and 1360 can include any suitable structure, configuration, arrangement, and/or components that enable the deposition source system 1300 to deposit a silver-carbon nanocomposite film stack according to embodiments. For example, but not limited to, the first and second sub-chambers 1350 and 1360 can include suitable deposition systems including coating sources, power sources, individual pressure controls, deposition control systems, and temperature control. In some embodiments, the sub-chambers are provided with individual gas supplies. As described and disclosed herein, the first and second sub-chambers 1350 and 1360 are typically separated from each other for providing good gas separation. The deposition source system 1300 described herein is not limited in the number of sub-chambers. For example, the deposition source system 1300 may include, but is not limited to, 3, 6, or 12 sub-chambers.

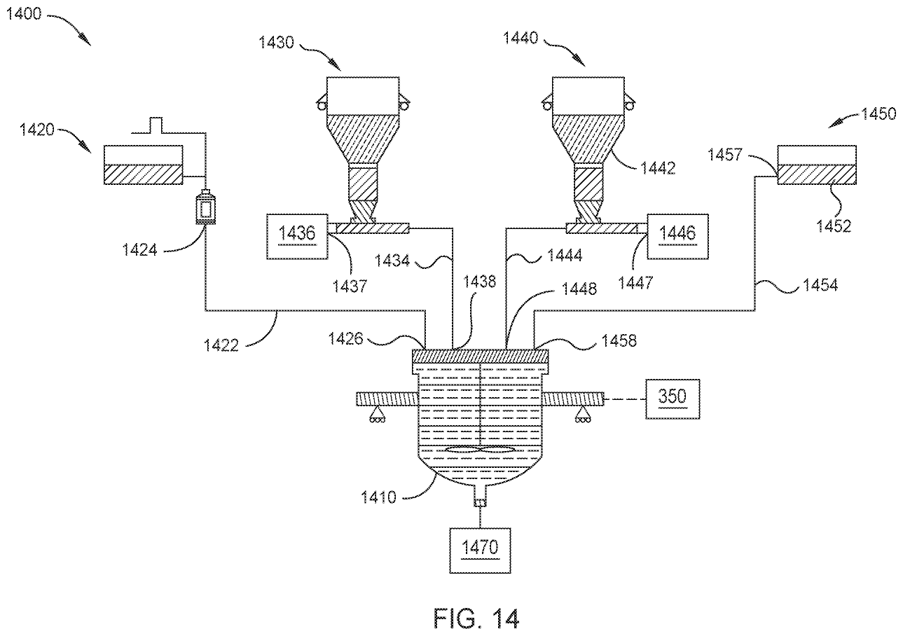

FIG. 14 illustrates a schematic view of a system 1400 for forming a silver-carbon (Ag—C) containing slurry 1470 according to one or more embodiments. The system 1400 includes a mixing vessel assembly 1410. The mixing vessel assembly 1410 is configured to mix various components to form a silver-carbon (Ag—C) containing slurry 1470. The silver-carbon (Ag—C) containing slurry 1470 can be used to form a silver-carbon nanocomposite. The mixing vessel assembly 1410 can be a rotary-type mixer. In some embodiments, the mixing vessel assembly 1410 is the mixing vessel assembly 800 depicted in FIG. 8.

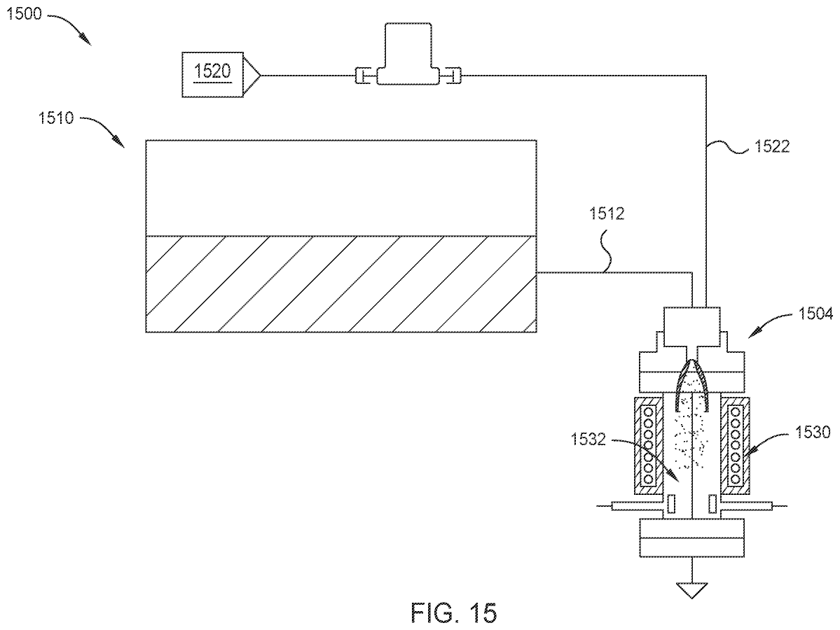

The system 1400 further includes a silver nanoparticle source 1420 operable to supply silver nanoparticles to the mixing vessel assembly 1410. The silver nanoparticle source 1420 is fluidly coupled with the mixing vessel assembly 1410 via a fluid delivery conduit 1422. The fluid delivery conduit 1422 is fluidly coupled with the silver nanoparticle source 1420 at a first end 1424 and the mixing vessel assembly 1410 at a second end 1426. In some embodiments, the silver nanoparticle source 1420 includes a spray pyrolysis system 1500 for forming the silver nanoparticles. The spray pyrolysis system 1500 will be discussed in further detail in FIG. 15.

The system 1400 further includes a carbon additive source vessel 1430 for supplying a carbon additive 1432 to the mixing vessel assembly 1410. The carbon additive source vessel 1430 is fluidly coupled with the mixing vessel assembly 1410 via a fluid delivery conduit 1434. In some embodiments, the carbon additive is selected from the group of graphite, graphene hard carbon, carbon black, carbon coated silicon, or any combination thereof. In some embodiments, the carbon additive source vessel 1430 is a hopper assembly. In one example, the carbon additive source is similar to the hopper assembly 710 depicted in FIG. 7 or the hopper assembly 950 depicted in FIG. 9. The fluid delivery conduit 1434 is fluidly coupled with an inert gas supply 1436 at a first end 1437 and the mixing vessel assembly 1410 at a second end 1438. The inert gas supply 1436 is positioned upstream relative to the carbon additive source vessel 1430. Inert gas, for example, argon, supplied from the inert gas supply 1436 can be used to deliver a desired amount of the carbon additive 1432 into the mixing vessel assembly 1410.

The system 1400 can further include a binding agent source vessel 1440 for supplying a binding agent 1442 to the mixing vessel assembly 1410. The binding agent source vessel 1440 is fluidly coupled with the mixing vessel assembly 1410 via a fluid delivery conduit 1444. In some embodiments, the binding agent is selected from styrene-butadiene rubber, acrylated styrene-butadiene rubber, acrylonitrile copolymer, acrylonitrile-butadiene rubber, nitrile butadiene rubber, acrylonitrile-styrene-butadiene copolymer, acryl rubber, butyl rubber, fluorine rubber, polytetrafluoroethylene, polyethylene, polypropylene, ethylene/propylene copolymers, polybutadiene, polyethylene oxide, chlorosulfonated polyethylene, polyvinylpyrrolidone, polyvinylpyridine, polyvinyl alcohol, polyvinyl acetate, polyepichlorohydrin, polyphosphazene, polyacrylonitrile, polystyrene, latex, acrylic resins, phenolic resins, epoxy resins, carboxymethyl cellulose, hydroxypropyl cellulose, cellulose acetate, cellulose acetate butyrate, cellulose acetate propionate, cyanoethylcellulose, cyanoethylsucrose, polyester, polyimide, polyether, polyimide, polycarboxylate, polycarboxylic acid, polyacrylic acid, polyacrylate, polymethacrylic acid, polymethacrylate, polyacrylamide, polyurethane, fluorinated polymer, chlorinated polymer, a salt of alginic acid, polyvinylidene fluoride, poly(vinylidene fluoride)-hexafluoropropene, or a combinations thereof. In some embodiments, the binding agent source vessel 1440 is a hopper assembly. In one example, binding agent source vessel 1440 is similar to the hopper assembly 710 depicted in FIG. 7 or the hopper assembly 950 depicted in FIG. 9. The fluid delivery conduit 1444 is fluidly coupled with an inert gas supply 1446 at a first end 1447 and the mixing vessel assembly 1410 at a second end 1448. The inert gas supply 1446 is positioned upstream relative to the binding agent source vessel 1440. Inert gas, for example, argon, supplied from the inert gas supply 1446 can be used to deliver a desired amount of the binding agent 1442 into the mixing vessel assembly 1410.

The system 1400 can further include a solvent source vessel 1450 for supplying a solvent 1452 to the mixing vessel assembly 1410. The solvent 1452 is fluidly coupled with the mixing vessel assembly 1410 via a fluid delivery conduit 1454. In some embodiments, the solvent 1452 is selected from the group of N-methyl-2-pyrrolidone, dimethylformamide, dimethyl sulfoxide, acetonitrile, butylene carbonate, propylene carbonate, ethyl bromide, tetrahydrofuran, dimethyl carbonate, diethyl carbonate, ethyl methyl, carbonate methyl propyl carbonate, ethylene carbonate, water, pure water, de-ionized water, distilled water, ethanol, isopropanol, methanol, acetone, n-propanol, t-butanol, or any combination thereof. The fluid delivery conduit 1454 is fluidly coupled with the solvent source vessel 1450 at a first end 1457 and the mixing vessel assembly 1410 at a second end 1458.

The silver-carbon (Ag—C) containing slurry 1470 is prepared by mixing the anode active material with other materials such as a carbon additive and binding agent in a solvent. The mixing process aims to achieve a uniform dispersion of the particles of the anode active material, carbon additive and binding agent in solvent. In operation, silver nanoparticles, carbon additives, binding agents, and/or solvents are sequentially introduced into the mixing vessel assembly 1410. The mixing vessel assembly 1410 can be heated. Introduction of the silver nanoparticles, the carbon additives, the binding agents, and/or solvents can be sequentially repeated to form alternating layers of silver nanoparticles, carbon additives, binding agents, and/or solvents within the mixing vessel assembly until a desired amount of each component is present in the mixing vessel assembly. Not to be bound by theory but it is believed that sequential introduction of the slurry-forming components into the mixing vessel assembly 1410 provides for a more homogenous slurry mixture.

FIG. 15 illustrates a schematic view of a spray pyrolysis system 1500 according to one or more embodiments. The spray pyrolysis system includes an ultrasonic spray deposition nozzle 1504. The spray pyrolysis system 1500 includes a silver solution source vessel 1510, for example, a silver nitrate (AgNO₃) solution. The silver solution source vessel 1510 is fluidly coupled with the ultrasonic spray deposition nozzle 1504 via fluid delivery line 1512. The spray pyrolysis system 1500 can further include an inert gas source 1520, for example, an argon gas source. The inert gas source 1520 is fluidly coupled with the ultrasonic spray deposition nozzle 1504 via a fluid delivery line 1522. The spray pyrolysis system 1500 further includes a heating element 1530, which can be positioned downstream from the ultrasonic spray deposition nozzle 1504. The heating element 1530 defines a nanoparticle formation region 1532 where the silver nanoparticles are formed. In operation, silver nitrate is delivered from silver solution source vessel 1510 to the ultrasonic spray deposition nozzle 1504. An ultrasonic frequency is applied to the silver nitrate solution to generate atomized droplets of the silver nitrate solution. The atomized droplets are entrained in a controlled jet of air as a carrier gas from the inert gas source 1520. The atomized droplets are delivered to and heated in the nanoparticle formation region 1532 where the atomized droplets are thermally converted to silver nanoparticles.

Embodiments can include one or more of the following potential advantages. In one aspect, methods and systems for forming lithium anode devices are provided. In one embodiment, methods and systems for forming pre-lithiated Group-IV alloy-type nanoparticles (NP's), for example, Li—Z where Z is Ge, Si, or Sn, are provided. In another embodiment, methods and systems for synthesizing Group-IV nanoparticles and alloying the Group-IV nanoparticles with lithium are provided. The Group-IV nanoparticles can be made on demand and premixed with anode materials or coated on anode materials. In yet another embodiment, methods and systems for forming lithium metal-free silver carbon (“Ag—C”) nanocomposites (NC's) are provided. In yet another embodiment, a method utilizing silver (PVD) and carbon (PECVD) co-deposition to make anode coatings that can regulate lithium nucleation energy to minimize dendrite formation is provided.

Embodiments and all of the functional operations described in this specification can be implemented in digital electronic circuitry, or in computer software, firmware, or hardware, including the structural means disclosed in this specification and structural equivalents thereof, or in combinations of them. Embodiments described herein can be implemented as one or more non-transitory computer program products, e.g., one or more computer programs tangibly embodied in a machine readable storage device, for execution by, or to control the operation of, data processing apparatus, e.g., a programmable processor, a computer, or multiple processors or computers.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them. Processors suitable for the execution of a computer program include, by way of example, both general and special purpose microprocessors, and any one or more processors of any kind of digital computer.

Computer readable media suitable for storing computer program instructions and data include all forms of nonvolatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

Embodiments of the present disclosure further relate to any one or more of the following examples 1-34:

1. A method of making a lithiated Group-IV nanoparticle, comprising: introducing a layer of Group-IV nanoparticles into a heated mixing vessel; introducing a layer comprising lithium into the heated mixing vessel; sequentially repeating introducing the layer of Group-IV nanoparticles and the layer comprising lithium into the heated mixing vessel; and alloying the Group-IV nanoparticles and with the lithium to form the lithiated Group-IV nanoparticles.

2. The method according to example 1, wherein the Group-IV nanoparticles are formed from a non-thermal plasma synthesis process.

3. The method according to example 1 or 2, wherein the lithiated Group-IV nanoparticles are an air-stable pre-lithiation reagent.

4. The method according to any one of examples 1-3, wherein introducing the layer of Group-IV nanoparticles into the heated mixing vessel comprises supplying molten lithium into the heated mixing vessel.

5. The method according to any one of examples 1-4, wherein introducing the layer of Group-IV nanoparticles into the heated mixing vessel comprises supplying lithium powder into the heated mixing vessel.

6. The method according to any one of examples 1-5, further comprising applying the lithiated Group-IV nanoparticles to a graphite anode to form a pre-lithiated graphite anode.

7. The method according to any one of examples 1-6, wherein applying the lithiated Group-IV nanoparticles to a graphite anode to form a pre-lithiated graphite anode comprises an industrial sifter feeder process.

8. The method according to any one of examples 1-7, wherein applying the lithiated Group-IV nanoparticles to a graphite anode to form a pre-lithiated graphite anode comprises an electrospray process.

9. The method according to any one of examples 1-8, wherein the Group-IV nanoparticles are selected from silicon nanoparticles, germanium nanoparticles, tin nanoparticles, carbon nanoparticles, or any combination thereof.

10. The method according to any one of examples 1-9, wherein the heated mixing vessel is a rotary planetary mixer.

11. The method according to any one of examples 1-10, further comprising: mixing the lithiated Group-IV nanoparticles to form a slurry.

12. The method according to any one of examples 1-11, wherein mixing the lithiated Group-IV nanoparticles to form the slurry comprises mixing the lithiated Group-IV nanoparticles with a conductive additive, a binding agent, a solvent, or any combination thereof.

13. The method according to any one of examples 1-12, further comprising: casting the slurry over an anode structure to form a pre-lithiated alloy-type anode.

14. A system for forming an anode structure, comprising: a lithium source module operable to supply lithium; a Group-IV nanoparticle source module operable to supply Group-IV nanoparticles; and a mixing vessel assembly, wherein the mixing vessel assembly is capable of heating the lithium and the Group-IV nanoparticles to produce pre-lithiated Group-IV alloy-type nanoparticles.

15. The system according to example 14, further comprising a deposition source module operable to deposit the pre-lithiated Group-IV alloy-type nanoparticles over a substrate.

16. The system according to example 14 or 15, wherein the deposition source module comprises: a sifter body; a hopper assembly; and a delivery conduit fluidly coupling the hopper assembly with the sifter body.

17. The system according to any one of examples 14-16, wherein the deposition source module comprises: a deposition module that defines a processing environment; a coating drum positioned in the processing environment and operable to transfer a flexible substrate; and an electrospray gun positioned in the processing environment and operable to deposit the pre-lithiated Group-IV alloy-type nanoparticles on the flexible substrate.

18. The system according to any one of examples 14-17, wherein the electrospray gun is a triboelectric powder spray gun or a corona spray gun.

19. The system according to any one of examples 14-18, further comprising: a hopper assembly operable for storing and supplying the lithiated Group-IV alloyed nanoparticles to the electrospray gun.

20. A method of forming an anode structure, comprising: forming a silver-carbon (Ag—C) nanocomposite over a current collector web, comprising: sputtering silver over the current collector web concurrently with plasma-enhanced chemical vapor deposition of amorphous carbon to form the silver-carbon nanocomposite over the current collector.

21. The method according to example 20, further comprising: depositing a layer of lithium over the silver-carbon nanocomposite.

22. The method according to example 20 or 21, wherein depositing the layer of lithium over the silver-carbon nanocomposite comprises thermally evaporating lithium.

23. The method according to any one of examples 20-22, wherein sputtering silver over the current collector is performed using a DC sputtering gun.

24. A flexible substrate coating system, comprising: an unwinding module housing a feed reel capable of providing a continuous sheet of flexible material; a winding module housing a take-up reel capable of storing the continuous sheet of flexible material; a processing module arranged downstream from the unwinding module, the processing module, comprising: a plurality of sub-chambers arranged in sequence, each configured to perform one or more processing operations to the continuous sheet of flexible material; and a coating drum capable of guiding the continuous sheet of flexible material past the plurality of sub-chambers along a travel direction, wherein the sub-chambers are radially disposed about the coating drum and a first sub-chamber of the plurality of sub-chambers, comprises: a first deposition source operable to deposit silver; and a second deposition source operable to deposit carbon.

25. The flexible substrate coating system according to example 24, wherein the first deposition source is a physical vapor deposition (PVD) source and the second deposition source is a plasma-enhanced chemical vapor deposition (PECVD) source.

26. The flexible substrate coating system according to example 24 or 25, wherein the physical vapor deposition source comprises a DC sputtering gun and the PECVD source comprises an electrode showerhead.

27. The flexible substrate coating system according to any one of examples 24-26, wherein the first sub-chamber is defined by a sub-chamber body with an edge shield positioned over the sub-chamber body.

28. The flexible substrate coating system according to any one of examples 24-27, wherein the edge shield has one or more apertures defining a pattern of evaporated material that is deposited on the continuous sheet of flexible material.

29. The flexible substrate coating system according to any one of examples 24-28, further comprising a second sub-chamber comprising a thermal evaporation source.

30. The flexible substrate coating system according to any one of examples 24-29, wherein the thermal evaporation source is configured to deposit lithium metal.

31. A method of forming a lithium-free silver-carbon (Ag—C) based slurry, comprising: forming silver nanoparticles via a spray pyrolysis process; and combining the silver nanoparticles with a conductive additive, a binding agent, and a solvent in a heated mixing vessel to form the lithium-free silver-carbon (Ag—C) based slurry.

32. The method according to example 31, wherein the conductive additive is selected from the group of graphite, graphene hard carbon, carbon black, carbon coated silicon, or any combination thereof.

33. The method according to example 31 or 32, wherein the binding agent is selected from styrene-butadiene rubber, acrylated styrene-butadiene rubber, acrylonitrile copolymer, acrylonitrile-butadiene rubber, nitrile butadiene rubber, acrylonitrile-styrene-butadiene copolymer, acryl rubber, butyl rubber, fluorine rubber, polytetrafluoroethylene, polyethylene, polypropylene, ethylene/propylene copolymers, polybutadiene, polyethylene oxide, chlorosulfonated polyethylene, polyvinylpyrrolidone, polyvinylpyridine, polyvinyl alcohol, polyvinyl acetate, polyepichlorohydrin, polyphosphazene, polyacrylonitrile, polystyrene, latex, acrylic resins, phenolic resins, epoxy resins, carboxymethyl cellulose, hydroxypropyl cellulose, cellulose acetate, cellulose acetate butyrate, cellulose acetate propionate, cyanoethylcellulose, cyanoethylsucrose, polyester, polyimide, polyether, polyimide, polycarboxylate, polycarboxylic acid, polyacrylic acid, polyacrylate, polymethacrylic acid, polymethacrylate, polyacrylamide, polyurethane, fluorinated polymer, chlorinated polymer, a salt of alginic acid, polyvinylidene fluoride, poly(vinylidene fluoride)-hexafluoropropene, or a combinations thereof.

34. The method according to any one of examples 31-33, wherein the solvent is selected from N-methyl-2-pyrrolidone, dimethylformamide, dimethyl sulfoxide, acetonitrile, butylene carbonate, propylene carbonate, ethyl bromide, tetrahydrofuran, dimethyl carbonate, diethyl carbonate, ethyl methyl, carbonate methyl propyl carbonate, ethylene carbonate, water, pure water, de-ionized water, distilled water, ethanol, isopropanol, methanol, acetone, n-propanol, t-butanol, or any combination thereof.

While the foregoing is directed to embodiments of the disclosure, other and further embodiments may be devised without departing from the basic scope thereof, and the scope thereof is determined by the claims that follow. All documents described herein are incorporated by reference herein, including any priority documents and/or testing procedures to the extent they are not inconsistent with this text. As is apparent from the foregoing general description and the specific embodiments, while forms of the present disclosure have been illustrated and described, various modifications can be made without departing from the spirit and scope of the present disclosure. Accordingly, it is not intended that the present disclosure be limited thereby. Likewise, the term “comprising” is considered synonymous with the term “including” or “having” for purposes of United States law. Likewise, whenever a composition, an element, or a group of elements is preceded with the transitional phrase “comprising”, it is understood that the same composition or group of elements with transitional phrases “consisting essentially of”, “consisting of”, “selected from the group of consisting of”, or “is” preceding the recitation of the composition, element, or elements and vice versa, are contemplated. When introducing elements of the present disclosure or exemplary aspects or embodiment(s) thereof, the articles “a,” “an,” “the” and “said” are intended to mean that there are one or more of the elements.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below.

1. A method of making a lithiated Group-IV nanoparticle, comprising:
introducing a layer of Group-IV nanoparticles into a heated mixing vessel;
introducing a layer comprising lithium into the heated mixing vessel;
sequentially repeating introducing the layer of Group-IV nanoparticles and the layer comprising lithium into the heated mixing vessel; and
alloying the Group-IV nanoparticles and with the lithium to form the lithiated Group-IV nanoparticles.

2. The method of claim 1, wherein the Group-IV nanoparticles are formed from a non-thermal plasma synthesis process.

3. The method of claim 1, wherein the lithiated Group-IV nanoparticles are an air-stable pre-lithiation reagent.

4. The method of claim 1, wherein introducing the layer of Group-IV nanoparticles into the heated mixing vessel comprises supplying molten lithium into the heated mixing vessel.

5. The method of claim 1, wherein introducing the layer of Group-IV nanoparticles into the heated mixing vessel comprises supplying lithium powder into the heated mixing vessel.

6. The method of claim 1, further comprising applying the lithiated Group-IV nanoparticles to a graphite anode to form a pre-lithiated graphite anode.

7. The method of claim 6, wherein applying the lithiated Group-IV nanoparticles to a graphite anode to form a pre-lithiated graphite anode comprises an industrial sifter feeder process.

8. The method of claim 6, wherein applying the lithiated Group-IV nanoparticles to a graphite anode to form a pre-lithiated graphite anode comprises an electrospray process.

9. The method of claim 1, wherein the Group-IV nanoparticles are selected from silicon nanoparticles, germanium nanoparticles, tin nanoparticles, carbon nanoparticles, or any combination thereof.

10. The method of claim 1, wherein the heated mixing vessel is a rotary planetary mixer.

11. The method of claim 10, further comprising mixing the lithiated Group-IV nanoparticles to form a slurry.

12. The method of claim 11, wherein mixing the lithiated Group-IV nanoparticles to form the slurry comprises mixing the lithiated Group-IV nanoparticles with a conductive additive, a binding agent, a solvent, or any combination thereof.

13. The method of claim 12, further comprising casting the slurry over an anode structure to form a pre-lithiated alloy-type anode.

14. A system for forming an anode structure, comprising:
a lithium source module operable to supply lithium;
a Group-IV nanoparticle source module operable to supply Group-IV nanoparticles; and
a mixing vessel assembly, wherein the mixing vessel assembly is capable of heating the lithium and the Group-IV nanoparticles to produce pre-lithiated Group-IV alloy-type nanoparticles.

15. The system of claim 14, further comprising a deposition source module operable to deposit the pre-lithiated Group-IV alloy-type nanoparticles over a substrate.

16. The system of claim 15, wherein the deposition source module comprises:
a sifter body;
a hopper assembly; and
a delivery conduit fluidly coupling the hopper assembly with the sifter body.

17. The system of claim 15, wherein the deposition source module comprises:
a deposition module that defines a processing environment;
a coating drum positioned in the processing environment and operable to transfer a flexible substrate; and
an electrospray gun positioned in the processing environment and operable to deposit the pre-lithiated Group-IV alloy-type nanoparticles on the flexible substrate.

18. The system of claim 17, wherein the electrospray gun is a triboelectric powder spray gun or a corona spray gun.

19. The system of claim 18, further comprising: a hopper assembly operable for storing and supplying the lithiated Group-IV alloyed nanoparticles to the electrospray gun.

20. A flexible substrate coating system, comprising:
an unwinding module housing a feed reel capable of providing a continuous sheet of flexible material;
a winding module housing a take-up reel capable of storing the continuous sheet of flexible material;
a processing module arranged downstream from the unwinding module, the processing module, comprising:
a plurality of sub-chambers arranged in sequence, each configured to perform one or more processing operations to the continuous sheet of flexible material; and
a coating drum capable of guiding the continuous sheet of flexible material past the plurality of sub-chambers along a travel direction, wherein the sub-chambers are radially disposed about the coating drum and a first sub-chamber of the plurality of sub-chambers, comprises:
a first deposition source operable to deposit silver; and
a second deposition source operable to deposit carbon.
